(19) United States
(12) Patent Application Publication
(10) Pub. No.: US 2026/0222111 A1
(43) Pub. Date: Jul. 30, 2026

(54) MLC POLAR CODES WITH MULTIPLE KERNELS

(71) Applicant: QUALCOMM Incorporated, San Diego, CA (US)

(72) Inventors: Peer BERGER, Hod Hasharon (IL); Shay LANDIS, Hod Hasharon (IL); Jacob PICK, Mevaseret Zion (IL)

(21) Appl. No.: 19/041,465

(22) Filed: Jan. 30, 2025

(51) Int. Cl. H04L 1/00; H03M 13/15; H04W 8/22

(52) U.S. Cl. CPC H04L 1/0058; H03M 13/1515; H04L 1/0003; H04W 8/22

(57) ABSTRACT

This disclosure provides systems, methods and apparatuses for communication with a multi-level coding scheme having different polar code kernels. A network entity transmits and a user equipment receives a configuration indicating a multi-level coding scheme for encoding a plurality of bits for transmission using a modulation scheme having a constellation size of more than 2 bits. The multi-level coding scheme has at least one first outer code with a first polar code kernel type and at least one second outer code with a second polar code kernel type that is different than the first polar code kernel type. Either the network entity or the user equipment can encode or decode a data transmission based on the multi-level coding scheme.

### TECHNICAL FIELD

The present disclosure relates to wireless communications including multi-level coding (MLC) polar codes with multiple kernels.

### DESCRIPTION OF THE RELATED TECHNOLOGY

Wireless communication systems are widely deployed to provide various telecommunication services such as telephony, video, data, messaging, and broadcasts. Typical wireless communication systems may employ multiple-access technologies capable of supporting communication with multiple users by sharing available system resources. Examples of such multiple-access technologies include code division multiple access (CDMA) systems, time division multiple access (TDMA) systems, frequency division multiple access (FDMA) systems, orthogonal frequency division multiple access (OFDMA) systems, single-carrier frequency division multiple access (SC-FDMA) systems, and time division synchronous code division multiple access (TD-SCDMA) systems.

These multiple access technologies have been adopted in various telecommunication standards to provide a common protocol that enables different wireless devices to communicate on a municipal, national, regional, and even global level. An example telecommunication standard is 5G New Radio (NR). 5G NR is part of a continuous mobile broadband evolution promulgated by Third Generation Partnership Project (3GPP) to meet new requirements associated with latency, reliability, security, scalability (such as with Internet of Things (IoT)), and other requirements. 5G NR includes services associated with enhanced mobile broadband (eMBB), massive machine type communications (mMTC), and ultra-reliable low latency communications (URLLC). Some aspects of 5G NR may be based on the 4G Long Term Evolution (LTE) standard.

### SUMMARY

The systems, methods and devices of this disclosure each have several innovative aspects, no single one of which is solely responsible for the desirable attributes disclosed herein.

In some aspects, the techniques described herein relate to an apparatus for wireless communication, the apparatus including: one or more memories storing executable instructions; and one or more processors coupled to the one or more memories and configured to execute the instructions to cause the apparatus to: receive a configuration indicating a multi-level coding scheme for encoding a plurality of bits for transmission using a modulation scheme having a constellation size of more than 2 bits, wherein the multi-level coding scheme has at least one first outer code with a first polar code kernel type and at least one second outer code with a second polar code kernel type that is different than the first polar code kernel type.

In some aspects, the techniques described herein relate to an apparatus for wireless communication, the apparatus including: one or more memories storing executable instructions; and one or more processors coupled to the one or more memories and configured to execute the instructions to cause the apparatus to: transmit a configuration indicating a multi-level coding scheme for encoding a plurality of bits for transmission using a modulation scheme having a constellation size of more than 2 bits, wherein the multi-level coding scheme has at least one first outer code with a first polar code kernel type and at least one second outer code with a second polar code kernel type that is different than the first polar code kernel type.

In some aspects, the techniques described herein relate to a method of wireless communication, including: receiving a configuration indicating a multi-level coding scheme for encoding a plurality of bits for transmission using a modulation scheme having a constellation size of more than 2 bits, wherein the multi-level coding scheme has at least one first outer code with a first polar code kernel type and at least one second outer code with a second polar code kernel type that is different than the first polar code kernel type.

In some aspects, the techniques described herein relate to a method of wireless communication, including: transmitting a configuration indicating a multi-level coding scheme for encoding a plurality of bits for transmission using a modulation scheme having a constellation size of more than 2 bits, wherein the multi-level coding scheme has at least one first outer code with a first polar code kernel type and at least one second outer code with a second polar code kernel type that is different than the first polar code kernel type.

Details of one or more implementations of the subject matter described in this disclosure are set forth in the accompanying drawings and the description below. Other features, aspects, and advantages will become apparent from the description, the drawings and the claims. Note that the relative dimensions of the following figures may not be drawn to scale.

### BRIEF DESCRIPTION OF THE DRAWINGS

FIG. 1 is a diagram illustrating an example of a wireless communications system including an access network.

FIG. 2A is a diagram illustrating an example of a first frame.

FIG. 2B is a diagram illustrating an example of DL channels within a subframe.

FIG. 2C is a diagram illustrating an example of a second frame.

FIG. 2D is a diagram illustrating an example of a subframe.

FIG. 3 is a diagram illustrating an example of a base station (BS) and user equipment (UE) in an access network.

FIG. 4 is a diagram illustrating an example disaggregated base station architecture.

FIG. 5 is a diagram of an example polar encoder for two bits.

FIG. 6 is a diagram of an example polar encoder for N bits using the polar encoder of FIG. 5 as a kernel.

FIG. 7 is a diagram of multi-level coding (MLC) with multiple outer codes.

FIG. 8 is a diagram of an example set partitioning scheme compatible with MLC.

FIG. 9 is a chart of bit channel capacity in a polar encoder.

FIG. 10 is a chart of symbol error rate in a polar MLC scheme.

FIG. 11 is a chart of a probability distribution function of errors in a polar MLC scheme with frozen bits.

FIG. 12 is a chart of block error rate for two different polar code kernels.

FIG. 13 is a diagram of MLC with outer codes having different polar code kernel types.

FIG. 14 is a message diagram illustrating configuration of a UE for MLC with different polar codes.

FIG. 15 is a conceptual data flow diagram illustrating the data flow between different means/components in an example network entity including a MLC configuration component.

FIG. 16 is a conceptual data flow diagram illustrating the data flow between different means/components in an example UE including a MLC component.

FIG. 17 is a flowchart of an example method for a wireless node such as a UE to communicate using an MLC scheme with different polar code kernels.

FIG. 18 is a flowchart of an example method for a wireless node such as a network entity to configure a UE for communication using an MLC scheme with different polar code kernels.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. Some of the examples in this disclosure are based on wireless and wired local area network (LAN) communication according to the Institute of Electrical and Electronics Engineers (IEEE) 802.11 wireless standards, the IEEE 802.3 Ethernet standards, and the IEEE 1901 Powerline communication (PLC) standards. However, the described implementations may be implemented in any device, system or network that is capable of transmitting and receiving RF signals according to any of the wireless communication standards, including any of the IEEE 802.11 standards, the Bluetooth® standard, code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1×EV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless, cellular or internet of things (IoT) network, such as a system utilizing 3G, 4G or 5G, 6G or further implementations thereof, technology.

In wireless communications, data is typically encoded to allow correction of errors and improved reliability of communications. Example encoding techniques used in wireless communications include turbo coding and low density parity check (LDPC) coding. In 5G standards, a polar code is used for some control channels. A polar code utilizes the polarization phenomenon to channelize certain input bits to provide high reliability. Polar codes were initially used with control channels having lower order modulation. The performance of polar codes is also desirable for data channels using higher order modulation.

In an aspect, the present application provides a multi-level coding (MLC) scheme using polar codes with multiple kernels. In particular, the MLC scheme includes a plurality of outer codes including at least one outer code using a first type of polar kernel that has better polarization than another of the outer codes.

In MLC with polar codes, the polarization phenomenon results in some bit channels with very high reliability. Bit channels with very low reliability can be assigned frozen bits with known values. Accordingly, most of the errors in an MLC polar code are likely to occur in relatively lower reliability bits that are not frozen. In some implementations, the first type of polar kernel is mapped to the lower reliability bits that are more likely to have errors. The first type of polar kernel can improve the reliability of those bits. The more reliable bits can be mapped to a second type of polar code that may have lower complexity than the first type of polar code. Accordingly, the overall reliability may be improved without greatly increasing the overall complexity.

Several aspects of telecommunication systems will now be presented with reference to various apparatus and methods. These apparatus and methods will be described in the following detailed description and illustrated in the accompanying drawings by various blocks, components, circuits, processes, algorithms, etc. (collectively referred to as “elements”). These elements may be implemented using electronic hardware, computer software, or any combination thereof. Whether such elements are implemented as hardware or software depends upon the particular application and design constraints imposed on the overall system.

By way of example, an element, or any portion of an element, or any combination of elements may be implemented as a “processing system” that includes one or more processors. Examples of processors include microprocessors, microcontrollers, graphics processing units (GPUs), central processing units (CPUs), application processors, digital signal processors (DSPs), reduced instruction set computing (RISC) processors, systems on a chip (SoC), baseband processors, field programmable gate arrays (FPGAs), programmable logic devices (PLDs), state machines, gated logic, discrete hardware circuits, and other suitable hardware configured to perform the various functionality described throughout this disclosure. The processor may include an interface or be coupled to an interface that can obtain or output signals. The processor may obtain signals via the interface and output signals via the interface. In some implementations, the interface may be a printed circuit board (PCB) transmission line. In some other implementations, the interface may include a wireless transmitter, a wireless transceiver, or a combination thereof. For example, the interface may include a radio frequency (RF) transceiver which can be implemented to receive or transmit signals, or both. One or more processors in the processing system may execute software. Software shall be construed broadly to mean instructions, instruction sets, code, code segments, program code, programs, subprograms, software components, applications, software applications, software packages, routines, subroutines, objects, executables, threads of execution, procedures, functions, etc., whether referred to as software, firmware, middleware, microcode, hardware description language, or otherwise.

Accordingly, in one or more example implementations, the functions described may be implemented in hardware, software, or any combination thereof. If implemented in software, the functions may be stored on or encoded as one or more instructions or code on a computer-readable medium. Computer-readable media includes computer storage media, which may be referred to as non-transitory computer-readable media. Non-transitory computer-readable media may exclude transitory signals. Storage media may be any available media that can be accessed by a computer. By way of example, and not limitation, such computer-readable media can include a random-access memory (RAM), a read-only memory (ROM), an electrically erasable programmable ROM (EEPROM), optical disk storage, magnetic disk storage, other magnetic storage devices, combinations of the aforementioned types of computer-readable media, or any other medium that can be used to store computer executable code in the form of instructions or data structures that can be accessed by a computer.

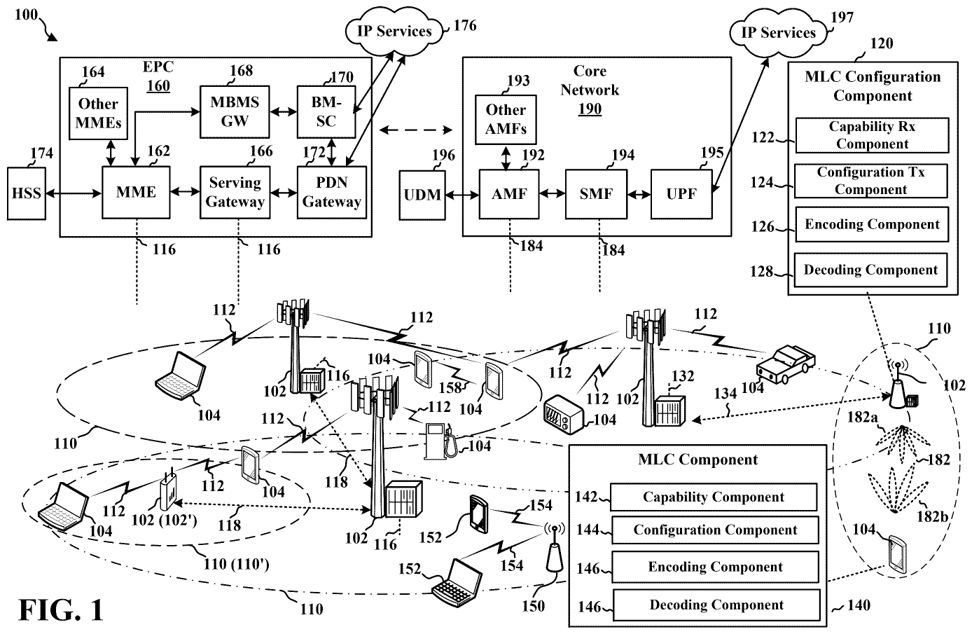

FIG. 1 is a diagram illustrating an example of a wireless communications system and an access network 100. The wireless communications system (also referred to as a wireless wide area network (WWAN)) includes wireless nodes such as base stations 102 and UEs 104, an Evolved Packet Core (EPC) 160, and another core network 190 (such as a 5G Core (5GC)). The base stations 102 may include macrocells (high power cellular base station) or small cells (low power cellular base station). The macrocells include base stations. The small cells include femtocells, picocells, and microcells. The small cells include femtocells, picocells, and microcells. The base stations 102 can be configured in a Disaggregated RAN (D-RAN) or Open RAN (O-RAN) architecture, where functionality is split between multiple units such as one or more central units (CUs) 188, one or more distributed units (DUs) 186, or a radio unit (RU) 180. Such architectures may be configured to utilize a protocol stack that is logically split between one or more units (such as one or more CUs and one or more DUs). In some aspects, the CUS 188 may be implemented within an edge RAN node, and in some aspects, one or more DUs 186 may be co-located with a CU 188, or may be geographically distributed throughout one or multiple RAN nodes. The DUs 186 may be implemented to communicate with one or more RUs 180.

In some implementations, one or more wireless nodes such as the UEs 104 include a MLC component 140 configured to implement a MLC scheme having at least one first outer code with a first polar code kernel type and at least one second outer code with a second polar code kernel type that is different than the first polar code kernel type. The MLC component 140 includes a capability component 142, a configuration component 144, an encoding component 146, and a decoding component 148. The capability component 142 is configured to transmit a capability message indicating a capability of the UE 104 with respect to the first polar code kernel type. The configuration component 144 is configured to receive a configuration indicating a multi-level coding scheme for encoding a plurality of bits for transmission using a modulation scheme having a constellation size of more than 2 bits. The encoding component 146 is configured to encode bits for transmission using the multi-level coding scheme. The decoding component 148 is configured to decode at least one modulated symbol based on the multi-level coding scheme.

In some implementations, one or more of wireless nodes such as the network entities including a base station 102 may include a MLC configuration component 120. In particular, the MLC configuration component 120 is configured to configure the UE 104 with the MLC scheme. The MLC configuration component 120 includes a capability RX component 122 and a configuration Tx component 124. The MLC configuration component 120 may also include an encoding component 126 and a decoding component 128. The capability RX component 122 is configured to receive a capability message indicating a capability of a UE 104 with respect to a first polar code kernel type. The configuration Tx component 124 is configured to transmit a configuration indicating a multi-level coding scheme for encoding a plurality of bits for transmission using a modulation scheme having a constellation size of more than 2 bits. The encoding component 126 is configured to encode bits for transmission using the multi-level coding scheme. The decoding component 128 is configured to decode at least one modulated symbol based on the multi-level coding scheme.

The base stations 102 configured for 4G LTE (collectively referred to as Evolved Universal Mobile Telecommunications System (UMTS) Terrestrial Radio Access Network (E-UTRAN)) may interface with the EPC 160 through first backhaul links 116 (such as S1 interface), which may be wired or wireless. The base stations 102 configured for 5G NR (collectively referred to as Next Generation RAN (NG-RAN)) may interface with core network 190 through second backhaul links 184, which may be wired or wireless. In addition to other functions, the base stations 102 may perform one or more of the following functions: transfer of user data, radio channel ciphering and deciphering, integrity protection, header compression, mobility control functions (such as handover, dual connectivity), inter-cell interference coordination, connection setup and release, load balancing, distribution for non-access stratum (NAS) messages, NAS node selection, synchronization, radio access network (RAN) sharing, multimedia broadcast multicast service (MBMS), subscriber and equipment trace, RAN information management (RIM), paging, positioning, and delivery of warning messages. The base stations 102 may communicate directly or indirectly (such as through the EPC 160 or core network 190) with each other over third backhaul links 118 (such as X2 interface). The third backhaul links 118 may be wired or wireless.

The base stations 102 may wirelessly communicate with the UEs 104. Each of the base stations 102 may provide communication coverage for a respective geographic coverage area 110. There may be overlapping geographic coverage areas 110. For example, the small cell 102′ may have a coverage area 110′ that overlaps the coverage area 110 of one or more macro base stations 102. A network that includes both small cell and macrocells may be known as a heterogeneous network. A heterogeneous network also may include Home Evolved Node Bs (eNBs) (HeNBs), which may provide service to a restricted group known as a closed subscriber group (CSG). The communication links 112 between the base stations 102 and the UEs 104 may include UL (also referred to as reverse link) transmissions from a UE 104 to a base station 102 or DL (also referred to as forward link) transmissions from a base station 102 to a UE 104. The communication links 112 may use multiple-input and multiple-output (MIMO) antenna technology, including spatial multiplexing, beamforming, or transmit diversity. The communication links may be through one or more carriers. The base stations 102/UEs 104 may use spectrum up to Y MHz (such as 5, 10, 15, 20, 100, 400, etc. MHz) bandwidth per carrier allocated in a carrier aggregation of up to a total of Yx MHz (x component carriers) used for transmission in each direction. The carriers may or may not be adjacent to each other.

Allocation of carriers may be asymmetric with respect to DL and UL (such as more or fewer carriers may be allocated for DL than for UL). The component carriers may include a primary component carrier and one or more secondary component carriers. A primary component carrier may be referred to as a primary cell (PCell) and a secondary component carrier may be referred to as a secondary cell (SCell).

Certain UEs 104 may communicate with each other using device-to-device (D2D) communication link 158. The D2D communication link 158 may use the DL/UL WWAN spectrum. The D2D communication link 158 may use one or more sidelink channels, such as a physical sidelink broadcast channel (PSBCH), a physical sidelink discovery channel (PSDCH), a physical sidelink shared channel (PSSCH), and a physical sidelink control channel (PSCCH). D2D communication may be through a variety of wireless D2D communications systems, such as for example, FlashLinQ, WiMedia, Bluetooth, ZigBee, Wi-Fi based on the IEEE 802.11 standard, LTE, or NR.

The wireless communications system may further include a Wi-Fi access point (AP) 150 in communication with Wi-Fi stations (STAs) 152 via communication links 154 in a 5 GHz unlicensed frequency spectrum. When communicating in an unlicensed frequency spectrum, the STAs 152/AP 150 may perform a clear channel assessment (CCA) prior to communicating in order to determine whether the channel is available.

The small cell 102′ may operate in a licensed or an unlicensed frequency spectrum. When operating in an unlicensed frequency spectrum, the small cell 102′ may employ NR and use the same 5 GHz unlicensed frequency spectrum as used by the Wi-Fi AP 150. The small cell 102′, employing NR in an unlicensed frequency spectrum, may boost coverage to or increase capacity of the access network.

A base station 102, whether a small cell 102′ or a large cell (such as macro base station), may include an eNB, gNodeB (gNB), or other type of base station. Some base stations, such as gNB may operate in one or more frequency bands within the electromagnetic spectrum.

The electromagnetic spectrum is often subdivided, based on frequency/wavelength, into various classes, bands, channels, etc. In 5G NR two initial operating bands have been identified as frequency range designations FR1 (410 MHz-7.125 GHz) and FR2 (24.25 GHz-52.6 GHz). The frequencies between FR1 and FR2 are often referred to as mid-band frequencies. Although a portion of FR1 is greater than 6 GHz, FR1 is often referred to (interchangeably) as a “Sub-6 GHz” band in various documents and articles. A similar nomenclature issue sometimes occurs with regard to FR2, which is often referred to (interchangeably) as a “millimeter wave” (mmW) band in documents and articles, despite being different from the extremely high frequency (EHF) band (30 GHz-300 GHz) which is identified by the International Telecommunications Union (ITU) as a “millimeter wave” band.

With the above aspects in mind, unless specifically stated otherwise, it should be understood that the term “sub-6 GHz” or the like if used herein may broadly represent frequencies that may be less than 6 GHz, may be within FR1, or may include mid-band frequencies. Further, unless specifically stated otherwise, it should be understood that the term “millimeter wave” or the like if used herein may broadly represent frequencies that may include mid-band frequencies, may be within FR2, or may be within the EHF band. Communications using the mmW radio frequency band have extremely high path loss and a short range. The mmW base station may utilize beamforming 182 with the UE 104 to compensate for the path loss and short range. For example, the base station 102 may use beamforming 182 to transmit beams 182a and the UE 104 may utilize beamforming 182 to transmit beams 182b.

The EPC 160 may include a Mobility Management Entity (MME) 162, other MMEs 164, a Serving Gateway 166, a Multimedia Broadcast Multicast Service (MBMS) Gateway 168, a Broadcast Multicast Service Center (BM-SC) 170, and a Packet Data Network (PDN) Gateway 172. The MME 162 may be in communication with a Home Subscriber Server (HSS) 174. The MME 162 is the control node that processes the signaling between the UEs 104 and the EPC 160. Generally, the MME 162 provides bearer and connection management. All user Internet protocol (IP) packets are transferred through the Serving Gateway 166, which itself is connected to the PDN Gateway 172. The PDN Gateway 172 provides UE IP address allocation as well as other functions. The PDN Gateway 172 and the BM-SC 170 are connected to the IP Services 176. The IP Services 176 may include the Internet, an intranet, an IP Multimedia Subsystem (IMS), a PS Streaming Service, or other IP services. The BM-SC 170 may provide functions for MBMS user service provisioning and delivery. The BM-SC 170 may serve as an entry point for content provider MBMS transmission, may be used to authorize and initiate MBMS Bearer Services within a public land mobile network (PLMN), and may be used to schedule MBMS transmissions. The MBMS Gateway 168 may be used to distribute MBMS traffic to the base stations 102 belonging to a Multicast Broadcast Single Frequency Network (MBSFN) area broadcasting a particular service, and may be responsible for session management (start/stop) and for collecting eMBMS related charging information.

The core network 190 may include an Access and Mobility Management Function (AMF) 192, other AMFs 193, a Session Management Function (SMF) 194, and a User Plane Function (UPF) 195. The AMF 192 may be in communication with a Unified Data Management (UDM) 196. The AMF 192 is the control node that processes the signaling between the UEs 104 and the core network 190. Generally, the AMF 192 provides QoS flow and session management. All user Internet protocol (IP) packets are transferred through the UPF 195. The UPF 195 provides UE IP address allocation as well as other functions. The UPF 195 is connected to the IP Services 197. The IP Services 197 may include the Internet, an intranet, an IP Multimedia Subsystem (IMS), a PS Streaming Service, or other IP services.

The base station may include or be referred to as a gNB, Node B, eNB, an access point, a base transceiver station, a radio base station, a radio transceiver, a transceiver function, a basic service set (BSS), an extended service set (ESS), a transmit reception point (TRP), or some other suitable terminology. The base station 102 provides an access point to the EPC 160 or core network 190 for a UE 104. Examples of UEs 104 include a cellular phone, a smart phone, a session initiation protocol (SIP) phone, a laptop, a personal digital assistant (PDA), a satellite radio, a global positioning system, a multimedia device, a video device, a digital audio player (such as a MP3 player), a camera, a game console, a tablet, a smart device, a wearable device, a vehicle, an electric meter, a gas pump, a large or small kitchen appliance, a healthcare device, an implant, a sensor/actuator, a display, or any other similar functioning device. Some of the UEs 104 may be referred to as IoT devices (such as a parking meter, gas pump, toaster, vehicles, heart monitor, etc.). The UE 104 also may be referred to as a station, a mobile station, a subscriber station, a mobile unit, a subscriber unit, a wireless unit, a remote unit, a mobile device, a wireless device, a wireless communications device, a remote device, a mobile subscriber station, an access terminal, a mobile terminal, a wireless terminal, a remote terminal, a handset, a user agent, a mobile client, a client, or some other suitable terminology.

Although the following description may be focused on 6G, the concepts described herein may be applicable to other similar areas, such as 5G NR, LTE, LTE-A, CDMA, GSM, and other wireless technologies including future wireless technologies.

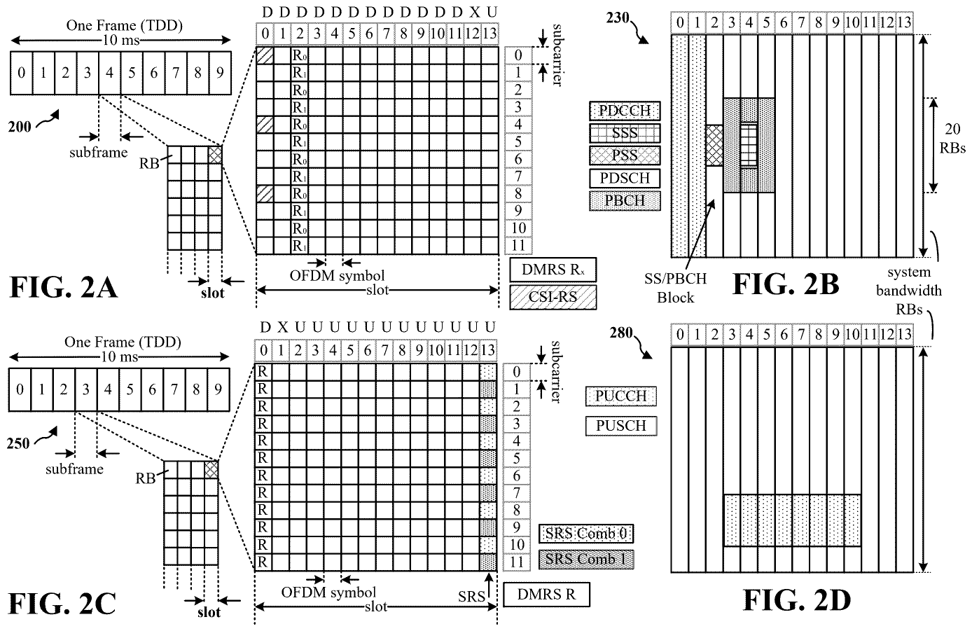

FIG. 2A is a diagram 200 illustrating an example of a first frame. FIG. 2B is a diagram 230 illustrating an example of DL channels within a subframe. FIG. 2C is a diagram 250 illustrating an example of a second frame. FIG. 2D is a diagram 280 illustrating an example of a subframe. The 5G NR frame structure may be FDD in which for a particular set of subcarriers (carrier system bandwidth), subframes within the set of subcarriers are dedicated for either DL or UL, or may be TDD in which for a particular set of subcarriers (carrier system bandwidth), subframes within the set of subcarriers are dedicated for both DL and UL. A subset of the total cell bandwidth of a cell is referred to as a Bandwidth Part (BWP) and bandwidth adaptation is achieved by configuring the UE with BWP(s) and telling the UE which of the configured BWPs is currently the active one. In an aspect, a narrow bandwidth part (NBWP) refers to a BWP having a bandwidth less than or equal to a maximum configurable bandwidth of a BWP. The bandwidth of the NBWP is less than the carrier system bandwidth.

In the examples provided by FIGS. 2A, 2C, the 5G NR frame structure is assumed to be TDD, with subframe 4 being configured with slot format 28 (with mostly DL), where D is DL, U is UL, and X is flexible for use between DL/UL, and subframe 3 being configured with slot format 34 (with mostly UL). While subframes 3, 4 are shown with slot formats 34, 28, respectively, any particular subframe may be configured with any of the various available slot formats 0-61. Slot formats 0, 1 are all DL, UL, respectively. Other slot formats 2-61 include a mix of DL, UL, and flexible symbols. UEs are configured with the slot format (dynamically through DL control information (DCI), or semi-statically/statically through radio resource control (RRC) signaling) through a received slot format indicator (SFI). Note that the description infra applies also to a 5G NR frame structure that is TDD.

Other wireless communication technologies may have a different frame structure or different channels. A frame (10 milliseconds (ms)) may be divided into 10 equally sized subframes (1 ms). Each subframe may include one or more time slots. Subframes also may include mini-slots, which may include 7, 4, or 2 symbols. Each slot may include 7 or 14 symbols, depending on the slot configuration. For slot configuration 0, each slot may include 14 symbols, and for slot configuration 1, each slot may include 7 symbols. The symbols on DL may be cyclic prefix (CP) OFDM (CP-OFDM) symbols. The symbols on UL may be CP-OFDM symbols (for high throughput scenarios) or discrete Fourier transform (DFT) spread OFDM (DFT-s-OFDM) symbols (also referred to as single carrier frequency-division multiple access (SC-FDMA) symbols) (for power limited scenarios; limited to a single stream transmission). The number of slots within a subframe is based on the slot configuration and the numerology. For slot configuration 0, different numerologies μ 0 to 5 allow for 1, 2, 4, 8, 16, and 32 slots, respectively, per subframe. For slot configuration 1, different numerologies 0 to 2 allow for 2, 4, and 8 slots, respectively, per subframe. Accordingly, for slot configuration 0 and numerology μ, there are 14 symbols/slot and 2^{μ} slots/subframe. The subcarrier spacing and symbol length/duration are a function of the numerology. The subcarrier spacing may be equal to 2^{μ}*15 kHz, where μ is the numerology 0 to 5. As such, the numerology μ=0 has a subcarrier spacing of 15 kHz and the numerology μ=5 has a subcarrier spacing of 480 kHz. The symbol length/duration is inversely related to the subcarrier spacing. FIGS. 2A-2D provide an example of slot configuration 0 with 14 symbols per slot and numerology μ=2 with 4 slots per subframe. The slot duration is 0.25 ms, the subcarrier spacing is 60 kHz, and the symbol duration is approximately 16.67 microseconds (μs).

A resource grid may be used to represent the frame structure. Each time slot includes a resource block (RB) (also referred to as physical RBs (PRBs)) that extends 12 consecutive subcarriers. The resource grid is divided into multiple resource elements (REs). The number of bits carried by each RE depends on the modulation scheme.

As illustrated in FIG. 2A, some of the REs carry reference (pilot) signals (RS) for the UE. The RS may include demodulation RS (DMRS) (indicated as Rx for one particular configuration, where 100x is the port number, but other DM-RS configurations are possible) and channel state information reference signals (CSI-RS) for channel estimation at the UE. The RS also may include beam measurement RS (BRS), beam refinement RS (BRRS), and phase tracking RS (PT-RS).

FIG. 2B illustrates an example of various DL channels within a subframe of a frame. The physical downlink control channel (PDCCH) carries DCI within one or more control channel elements (CCEs), each CCE including nine RE groups (REGs), each REG including four consecutive REs in an OFDM symbol. A primary synchronization signal (PSS) may be within symbol 2 of particular subframes of a frame. The PSS is used by a UE 104 to determine subframe/symbol timing and a L1 identity. A secondary synchronization signal (SSS) may be within symbol 4 of particular subframes of a frame. The SSS is used by a UE to determine a L1 cell identity group number and radio frame timing. Based on the L1 identity and the L1 cell identity group number, the UE can determine a physical cell identifier (PCI). Based on the PCI, the UE can determine the locations of the aforementioned DMRS. The physical broadcast channel (PBCH), which carries a master information block (MIB), may be logically grouped with the PSS and SSS to form a synchronization signal (SS)/PBCH block (SSB). The MIB provides a number of RBs in the system bandwidth and a system frame number (SFN). The physical downlink shared channel (PDSCH) carries user data, broadcast system information not transmitted through the PBCH such as system information blocks (SIBs), and paging messages.

As illustrated in FIG. 2C, some of the REs carry DM-RS (indicated as R for one particular configuration, but other DM-RS configurations are possible) for channel estimation at the base station. The UE may transmit DM-RS for the physical uplink control channel (PUCCH) and DM-RS for the physical uplink shared channel (PUSCH). The PUSCH DM-RS may be transmitted in the first one or two symbols of the PUSCH. The PUCCH DM-RS may be transmitted in different configurations depending on whether short or long PUCCHs are transmitted and depending on the particular PUCCH format used. The UE may transmit sounding reference signals (SRS). The SRS may be transmitted in the last symbol of a subframe. The SRS may have a comb structure, and a UE may transmit SRS on one of the combs. The SRS may be used by a base station for channel quality estimation to enable frequency-dependent scheduling on the UL.

FIG. 2D illustrates an example of various UL channels within a subframe of a frame. The PUCCH may be located as indicated in one configuration. The PUCCH carries uplink control information (UCI), such as scheduling requests, a channel quality indicator (CQI), a precoding matrix indicator (PMI), a rank indicator (RI), and HARQ ACK/NACK feedback. The PUSCH carries data, and may additionally be used to carry a buffer status report (BSR), a power headroom report (PHR), or UCI.

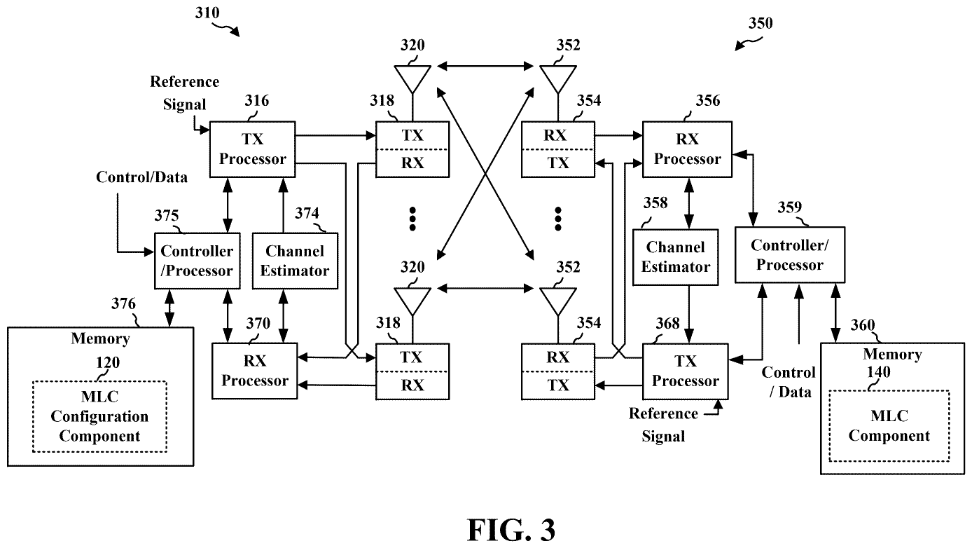

FIG. 3 is a diagram of an example of a base station 310 and a UE 350 in an access network. In the DL, IP packets from the EPC 160 may be provided to a controller/processor 375. The controller/processor 375 implements layer 3 and layer 2 functionality. Layer 3 includes a radio resource control (RRC) layer, and layer 2 includes a service data adaptation protocol (SDAP) layer, a packet data convergence protocol (PDCP) layer, a radio link control (RLC) layer, and a medium access control (MAC) layer. The controller/processor 375 provides RRC layer functionality associated with broadcasting of system information (such as MIB, SIBs), RRC connection control (such as RRC connection paging, RRC connection establishment, RRC connection modification, and RRC connection release), inter radio access technology (RAT) mobility, and measurement configuration for UE measurement reporting; PDCP layer functionality associated with header compression/decompression, security (ciphering, deciphering, integrity protection, integrity verification), and handover support functions; RLC layer functionality associated with the transfer of upper layer packet data units (PDUs), error correction through ARQ, concatenation, segmentation, and reassembly of RLC service data units (SDUs), re-segmentation of RLC data PDUs, and reordering of RLC data PDUs; and MAC layer functionality associated with mapping between logical channels and transport channels, multiplexing of MAC SDUs onto transport blocks (TBs), demultiplexing of MAC SDUs from TBs, scheduling information reporting, error correction through HARQ, priority handling, and logical channel prioritization.

The transmit (TX) processor 316 and the receive (RX) processor 370 implement layer 1 functionality associated with various signal processing functions. Layer 1, which includes a physical (PHY) layer, may include error detection on the transport channels, forward error correction (FEC) coding/decoding of the transport channels, interleaving, rate matching, mapping onto physical channels, modulation/demodulation of physical channels, and MIMO antenna processing. The TX processor 316 handles mapping to signal constellations based on various modulation schemes (such as binary phase-shift keying (BPSK), quadrature phase-shift keying (QPSK), M-phase-shift keying (M-PSK), M-quadrature amplitude modulation (M-QAM)). The coded and modulated symbols may be split into parallel streams. Each stream may be mapped to an OFDM subcarrier, multiplexed with a reference signal (such as a pilot) in the time or frequency domain, and combined together using an Inverse Fast Fourier Transform (IFFT) to produce a physical channel carrying a time domain OFDM symbol stream. The OFDM stream is spatially precoded to produce multiple spatial streams. Channel estimates from a channel estimator 374 may be used to determine the coding and modulation scheme, as well as for spatial processing. The channel estimate may be derived from a reference signal or channel condition feedback transmitted by the UE 350. Each spatial stream may be provided to a different antenna 320 via a separate transmitter 318TX. Each transmitter 318TX may modulate an RF carrier with a respective spatial stream for transmission. In a split architecture, the transmitters/receivers 318 may be located in an RU 180, and the Tx processor 316, channel estimator 374, controller/processor 375, and Rx processor 370 may be located in a DU 186.

At the UE 350, each receiver 354RX receives a signal through its respective antenna 352. Each receiver 354RX recovers information modulated onto an RF carrier and provides the information to the receive (RX) processor 356. The TX processor 368 and the RX processor 356 implement layer 1 functionality associated with various signal processing functions. The RX processor 356 may perform spatial processing on the information to recover any spatial streams destined for the UE 350. If multiple spatial streams are destined for the UE 350, they may be combined by the RX processor 356 into a single OFDM symbol stream. The RX processor 356 converts the OFDM symbol stream from the time-domain to the frequency domain using a Fast Fourier Transform (FFT). The frequency domain signal includes a separate OFDM symbol stream for each subcarrier of the OFDM signal. The symbols on each subcarrier, and the reference signal, are recovered and demodulated by determining the most likely signal constellation points transmitted by the base station 310. These soft decisions may be based on channel estimates computed by the channel estimator 358. The soft decisions are decoded and deinterleaved to recover the data and control signals that were originally transmitted by the base station 310 on the physical channel. The data and control signals are provided to the controller/processor 359, which implements layer 3 and layer 2 functionality.

The controller/processor 359 can be associated with a memory 360 that stores program codes and data. The memory 360 may be referred to as a computer-readable medium. In the UL, the controller/processor 359 provides demultiplexing between transport and logical channels, packet reassembly, deciphering, header decompression, and control signal processing to recover IP packets from the EPC 160. The controller/processor 359 is also responsible for error detection using an ACK or NACK protocol to support HARQ operations.

Similar to the functionality described in connection with the DL transmission by the base station 310, the controller/processor 359 provides RRC layer functionality associated with system information (such as MIB, SIBs) acquisition, RRC connections, and measurement reporting; PDCP layer functionality associated with header compression/decompression, and security (ciphering, deciphering, integrity protection, integrity verification); RLC layer functionality associated with the transfer of upper layer PDUs, error correction through ARQ, concatenation, segmentation, and reassembly of RLC SDUs, re-segmentation of RLC data PDUs, and reordering of RLC data PDUs; and MAC layer functionality associated with mapping between logical channels and transport channels, multiplexing of MAC SDUs onto TBs, demultiplexing of MAC SDUs from TBs, scheduling information reporting, error correction through HARQ, priority handling, and logical channel prioritization.

Channel estimates derived by a channel estimator 358 from a reference signal or feedback transmitted by the base station 310 may be used by the TX processor 368 to select the appropriate coding and modulation schemes, and to facilitate spatial processing. The spatial streams generated by the TX processor 368 may be provided to different antenna 352 via separate transmitters 354TX. Each transmitter 354TX may modulate an RF carrier with a respective spatial stream for transmission.

The UL transmission is processed at the base station 310 in a manner similar to that described in connection with the receiver function at the UE 350. Each receiver 318RX receives a signal through its respective antenna 320. Each receiver 318RX recovers information modulated onto an RF carrier and provides the information to a RX processor 370.

The controller/processor 375 can be associated with a memory 376 that stores program codes and data. The memory 376 may be referred to as a computer-readable medium. In the UL, the controller/processor 375 provides demultiplexing between transport and logical channels, packet reassembly, deciphering, header decompression, control signal processing to recover IP packets from the UE 350. IP packets from the controller/processor 375 may be provided to the EPC 160. The controller/processor 375 is also responsible for error detection using an ACK or NACK protocol to support HARQ operations.

At least one of the TX processor 368, the RX processor 356, and the controller/processor 359 may be configured to perform aspects in connection with the MLC component 140 of FIG. 1. For example, the memory 360 may include executable instructions defining the MLC component 140. The TX processor 368, the RX processor 356, and/or the controller/processor 359 may be configured to execute the MLC component 140.

At least one of the TX processor 316, the RX processor 370, and the controller/processor 375 may be configured to perform aspects in connection with the MLC configuration component 120 of FIG. 1. For example, the memory 376 may include executable instructions defining the MLC configuration component 120. The TX processor 316, the RX processor 370, and/or the controller/processor 375 may be configured to execute the MLC configuration component 120.

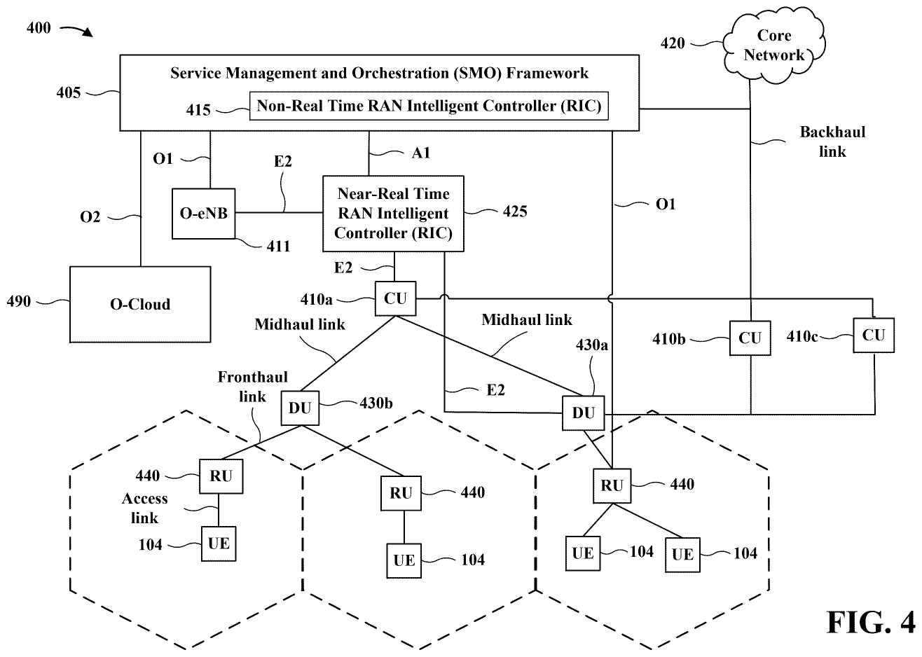

FIG. 4 is a diagram illustrating an example disaggregated base station 400 architecture. The disaggregated base station 400 architecture may include one or more central units (CUs) 410 that can communicate directly with a core network 420 via a backhaul link, or indirectly with the core network 420 through one or more disaggregated base station units (such as a Near-Real Time (Near-RT) RAN Intelligent Controller (RIC) 425 via an E2 link, or a Non-Real Time (Non-RT) RIC 415 associated with a Service Management and Orchestration (SMO) Framework 405, or both). A CU 410 may communicate with one or more distributed units (DUs) 430 via respective midhaul links, such as an F1 interface. The DUs 430 may communicate with one or more radio units (RUs) 440 via respective fronthaul links. The RUs 440 may communicate with respective UEs 104 via one or more radio frequency (RF) access links. In some implementations, the UE 104 may be simultaneously served by multiple RUs 440.

Each of the units, i.e., the CUS 410, the DUs 430, the RUs 440, as well as the Near-RT RICs 425, the Non-RT RICs 415 and the SMO Framework 405, may include one or more interfaces or be coupled to one or more interfaces configured to receive or transmit signals, data, or information (collectively, signals) via a wired or wireless transmission medium. Each of the units, or an associated processor or controller providing instructions to the communication interfaces of the units, can be configured to communicate with one or more of the other units via the transmission medium. For example, the units can include a wired interface configured to receive or transmit signals over a wired transmission medium to one or more of the other units. Additionally, the units can include a wireless interface, which may include a receiver, a transmitter or transceiver (such as a radio frequency (RF) transceiver), configured to receive or transmit signals, or both, over a wireless transmission medium to one or more of the other units.

In some aspects, the CU 410 may host one or more higher layer control functions. Such control functions can include radio resource control (RRC), packet data convergence protocol (PDCP), service data adaptation protocol (SDAP), or the like. Each control function can be implemented with an interface configured to communicate signals with other control functions hosted by the CU 410. The CU 410 may be configured to handle user plane functionality (i.e., Central Unit-User Plane (CU-UP)), control plane functionality (i.e., Central Unit-Control Plane (CU-CP)), or a combination thereof. In some implementations, the CU 410 can be logically split into one or more CU-UP units and one or more CU-CP units. The CU-UP unit can communicate bidirectionally with the CU-CP unit via an interface, such as the E1 interface when implemented in an O-RAN configuration. The CU 410 can be implemented to communicate with the DU 430, as necessary, for network control and signaling.

The DU 430 may correspond to a logical unit that includes one or more base station functions to control the operation of one or more RUs 440. In some aspects, the DU 430 may host one or more of a radio link control (RLC) layer, a medium access control (MAC) layer, and one or more high physical (PHY) layers (such as modules for forward error correction (FEC) encoding and decoding, scrambling, modulation and demodulation, or the like) depending, at least in part, on a functional split, such as those defined by the 3^{rd} Generation Partnership Project (3GPP). In some aspects, the DU 430 may further host one or more low PHY layers. Each layer (or module) can be implemented with an interface configured to communicate signals with other layers (and modules) hosted by the DU 430, or with the control functions hosted by the CU 410.

Lower-layer functionality can be implemented by one or more RUs 440. In some deployments, an RU 440, controlled by a DU 430, may correspond to a logical node that hosts RF processing functions, or low-PHY layer functions (such as performing fast Fourier transform (FFT), inverse FFT (iFFT), digital beamforming, physical random access channel (PRACH) extraction and filtering, or the like), or both, based at least in part on the functional split, such as a lower layer functional split. In such an architecture, the RU(s) 440 can be implemented to handle over the air (OTA) communication with one or more UEs 104. In some implementations, real-time and non-real-time aspects of control and user plane communication with the RU(s) 440 can be controlled by the corresponding DU 430. In some scenarios, this configuration can enable the DU(s) 430 and the CU 410 to be implemented in a cloud-based RAN architecture, such as a vRAN architecture.

The SMO Framework 405 may be configured to support RAN deployment and provisioning of non-virtualized and virtualized network elements. For non-virtualized network elements, the SMO Framework 405 may be configured to support the deployment of dedicated physical resources for RAN coverage requirements which may be managed via an operations and maintenance interface (such as an O1 interface). For virtualized network elements, the SMO Framework 405 may be configured to interact with a cloud computing platform (such as an open cloud (O-Cloud) 490) to perform network element life cycle management (such as to instantiate virtualized network elements) via a cloud computing platform interface (such as an O2 interface). Such virtualized network elements can include, but are not limited to, CUs 410, DUs 430, RUs 440 and Near-RT RICs 425. In some implementations, the SMO Framework 405 can communicate with a hardware aspect of a 4G RAN, such as an open eNB (O-eNB) 411, via an O1 interface. Additionally, in some implementations, the SMO Framework 405 can communicate directly with one or more RUs 440 via an O1 interface. The SMO Framework 405 also may include a Non-RT RIC 415 configured to support functionality of the SMO Framework 405.

The Non-RT RIC 415 may be configured to include a logical function that enables non-real-time control and optimization of RAN elements and resources, Artificial Intelligence/Machine Learning (AI/ML) workflows including model training and updates, or policy-based guidance of applications/features in the Near-RT RIC 425. The Non-RT RIC 415 may be coupled to or communicate with (such as via an A1 interface) the Near-RT RIC 425. The Near-RT RIC 425 may be configured to include a logical function that enables near-real-time control and optimization of RAN elements and resources via data collection and actions over an interface (such as via an E2 interface) connecting one or more CUs 410, one or more DUs 430, or both, as well as an O-eNB, with the Near-RT RIC 425.

In some implementations, to generate AI/ML models to be deployed in the Near-RT RIC 425, the Non-RT RIC 415 may receive parameters or external enrichment information from external servers. Such information may be utilized by the Near-RT RIC 425 and may be received at the SMO Framework 405 or the Non-RT RIC 415 from non-network data sources or from network functions. In some examples, the Non-RT RIC 415 or the Near-RT RIC 425 may be configured to tune RAN behavior or performance. For example, the Non-RT RIC 415 may monitor long-term trends and patterns for performance and employ AI/ML models to perform corrective actions through the SMO Framework 405 (such as reconfiguration via O1) or via creation of RAN management policies (such as A1 policies).

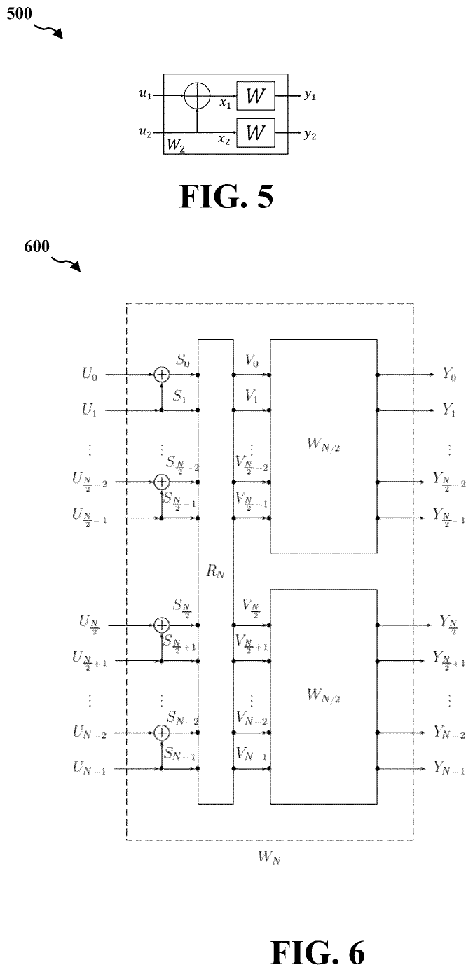

FIG. 5 is a diagram of an example polar encoder 500 for two bits. The input and output of the polar encoder 500 are of the same length (N). The illustrated polar encoder 500 is referred to as a [u+v,v] kernel.

$${G}_{[ u + v , v ] 2} = {F}_{u + v , v} = [ \begin{matrix}1 & 0 \\ 1 & 1\end{matrix} ]$$

$${U}_{1}^{2} \cdot {G}_{2} = {X}_{1}^{2}$$

$${X}_{1}^{2} \to {W}_{1}^{2} \to {Y}_{1}^{2}$$

FIG. 6 is a diagram of an example polar encoder 600 for N bits using the polar encoder 500 as a [u+v,v] kernel. N is a power of 2.

$${G}_{[ u + v , v ] N} = {B}_{[ binary ] N} \cdot {F}_{u + v , v}^{⊗ n}$$

$${U}_{0}^{N - 1} \cdot {G}_{N} = {X}_{0}^{N - 1}$$

$${X}_{0}^{N - 1} \to {W}_{0}^{N - 1} \to {Y}_{0}^{N - 1}$$

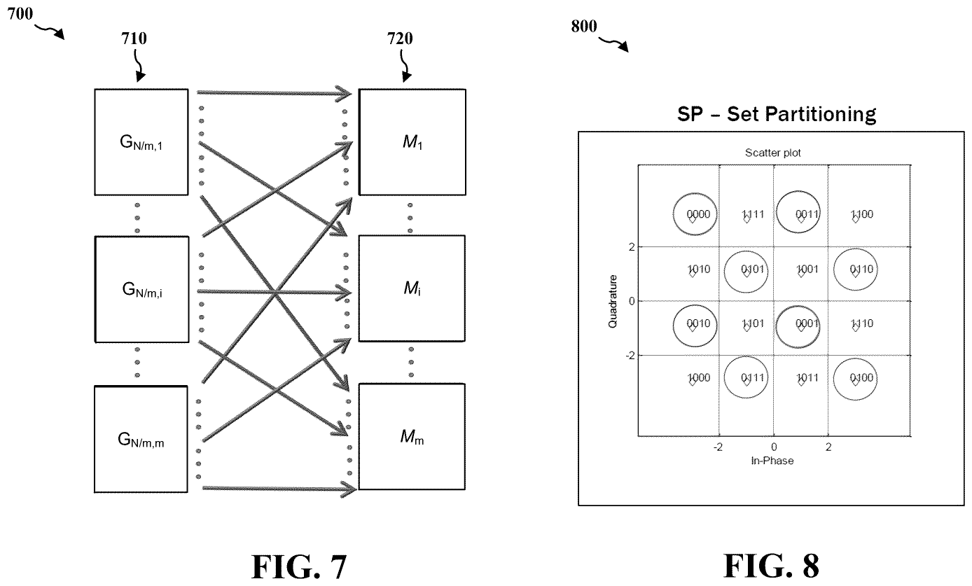

FIG. 7 is a diagram 700 of a multi-level coding (MLC) scheme with multiple outer codes 710. In an MLC scheme, there may be a number of outer codes 710 (G_{N/m}) equal to the number of bits in the constellation. For example, as illustrated, each outer code 710 is binary. Each outer code G_{N/m,i} is connected to the i'th bit (Mᵢ) in the constellation for each modulation symbol 720. MLC is optimal from the information chain rule:

$$I ( U ; Y ) = {\sum }_{l = 1}^{m} I ( {U}_{i} ; Y \vert {U}_{1}^{i - 1} )$$

FIG. 8 is a diagram of an example set partitioning scheme compatible with MLC. Set partitioning labeling maximizes the Euclidian distance between each bit of the constellation. For instance, the points with the first bit of 0 are circled whereas the points with the first bit of 1 are not circled. This improves sequential decoding because once a first bit is known, the Euclidian distance between potential constellation points for the next bit is increased.

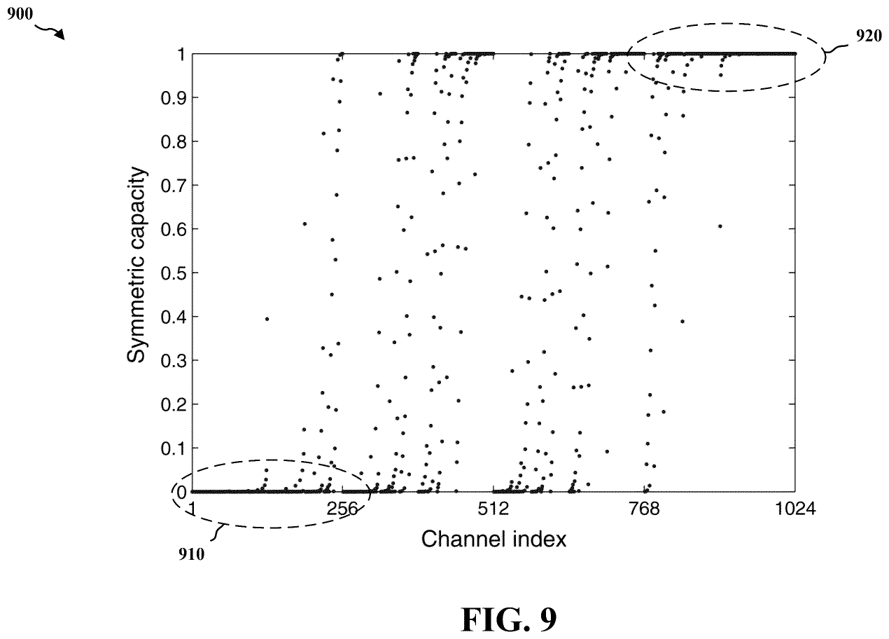

FIG. 9 is a chart 900 of bit channel capacity in a polar encoder. A polar encoder operates on the polarization phenomenon that channelizes the input bits.

$$\{ \begin{matrix}\vert {I}_{i} > 1 - ε \vert \\ \vert {I}_{i} < ε \vert \\ \vert ε < {I}_{i} < 1 - ε \vert\end{matrix} {\to }^{N \to ∞} \{ \begin{matrix}I ( U ; Y ) \\ 1 - I ( U ; Y ) \\ 0\end{matrix}$$

Some of the input bits will see a bit channel with a bit error rate (BER) of 0 indicating a capacity of 1. Some of the bits will see a bit channel with a BER of 0.5 indicating a capacity of 0. The proportion of noiseless bit channels converges (for N that is large enough) to the channel capacity. For encoding, the channel capacity and value of N is given. The indices of the N bit channels can be sorted. To transmit using rate R, the data can be transmitted in the best (maximal capacity or minimum BER) K bit channels, where K/N=R. The other N−K bits can have fixed values known to the decoder and referred to as frozen bits.

Decoding of a polar encoded transmission can use a successive cancellation list (SLC) decoder, which produces good block error rate (BLER) performance. The decoder complexity is O(L·N·log(N)). Accordingly, the shorter the block length, the less complexity.

In polar codes, the bit channels generally improve with the index. That is, the BER is generally lower and the capacity is higher for higher index bits. The chart 900 shows the symmetric capacity for binary phase shift keying (BPSK) modulation with N=1024. In particular, the channels 910 with bit indices less than approximately 256 have low capacity whereas the channels 920 with bit indices greater than 768 have high capacity.

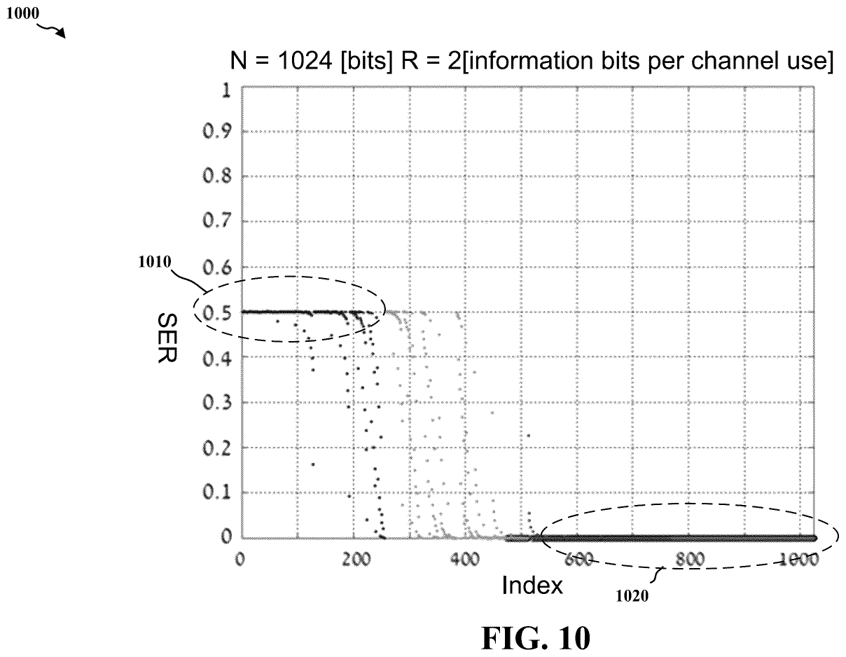

FIG. 10 is a chart of symbol error rate in a polar MLC scheme. In MLC, the above phenomenon is even more extreme due to the increase of Euclidean distance between bit levels. The illustrated chart 1000 shows an example of symbol error rate with a 4-bit modulation with N=1024 and R=2. The symbol error rate refers to the error rate of input symbols, which may be a tuple of 1 or more bits. As discussed above, polar decoders are more efficient in extreme rates (close to zero or one). Accordingly, the channels with indices less than approximately 200 may have low capacity, whereas the channels with indices greater than approximately 550 may have a capacity of 1.

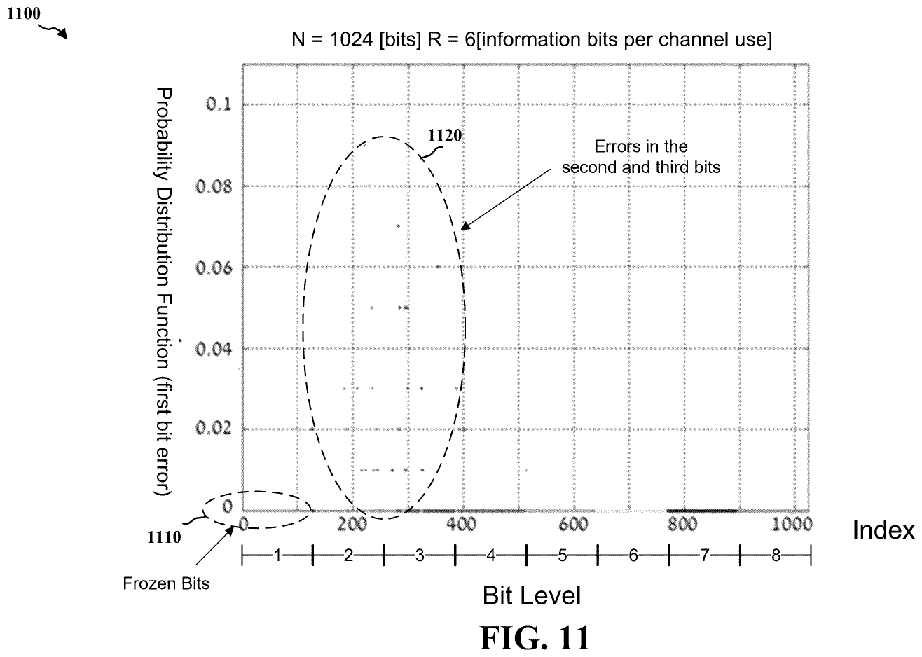

FIG. 11 is a chart 1100 of a probability distribution function of errors in a polar MLC scheme with frozen bits. The chart 1100 is for an 8-bit polar MLC scheme with N=1024 and R=6. In polar coding, the channel indices with the lowest capacity are mapped to frozen bits 1110. Because the frozen bits 1110 are known, any errors can be ignored and are not shown in the chart 1100. In the illustrated example, the frozen bits include most of the first level bits. Most of the errors occur in a region 1120 that corresponds to the second and third level bits. Bit levels 4-8 experience almost no errors.

In an aspect, multi-level polar coding can be improved by addressing the errors in the low level bits that are not frozen bits. In contrast, improvements to the higher level bits may not be productive as there are no errors in the higher level bits.

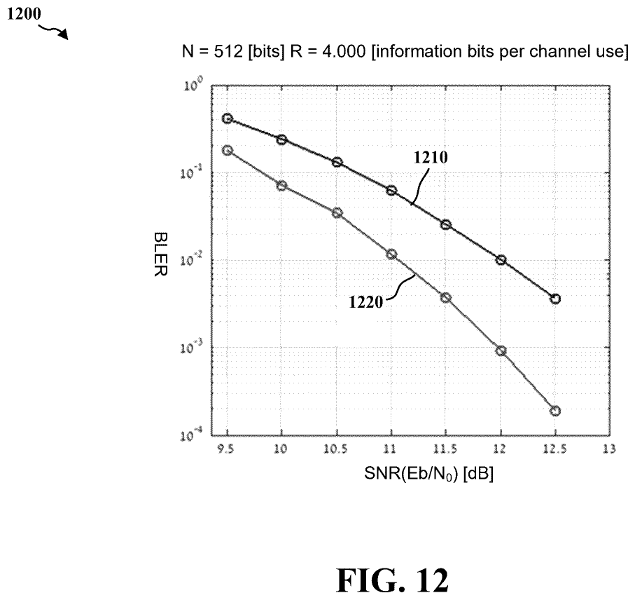

FIG. 12 is a chart 1200 of block error rate for two different polar code kernels. The two different polar encoders are applied to 256 quadrature amplitude modulation (QAM) with N=512 bits and R=4. The first polar encoder 1210 corresponds to the polar encoder 500 with the [u+v,v] kernel. The second polar encoder 1220 corresponds to a Reed-Solomon kernel over Galois field (4) (RS4 kernel). The RS4 kernel has a quadratic alphabet.

$${G}_{RS 4} = [ \begin{matrix}1 & 1 & 1 & 0 \\ α & {α}^{2} & 1 & 0 \\ {α}^{2} & α & 1 & 0 \\ 1 & 1 & 1 & α\end{matrix} ] \begin{matrix}( 0 , 0 ) ↔ 0 \\ ( 0 , 1 ) ↔ α \\ ( 1 , 1 ) ↔ {α}^{2} \\ ( 0 , 0 ) ↔ 1 or {α}^{3}\end{matrix}$$

The RS4 kernel is considered a better polarizing kernel than the [u+v,v] kernel. As such, the RS4 kernel has a better error exponent and can improve the finite length performance of the polar code. The downside of using a better polarizing kernel over a higher alphabet is higher complexity.

In an aspect, the present disclosure provides multi-level polar encoders using two or more kernel types. A first kernel type may be the better polarizing kernel (e.g., RS4). The second kernel type may be the standard [u+v,v] kernel. The first kernel type may be mapped to channel indices or bit levels where errors are more likely. The second kernel type may be used for the other channels indices and bit levels. Accordingly, the error rate of the lower capacity channels may be improved without increasing the complexity of the higher capacity channels.

For example, referring back to FIG. 11, the decoding results may be improved by replacing bit levels 2 and 3 with the RS4 kernel while all other bit levels will continue using the regular [u+v,v] kernel. Accordingly, only the complexity of 2 of the 8 bits is increased. Because RS4 is over GF(4), the outer code using the RS4 kernel must be mapped into 2 consecutive bits in the constellation. Another option is replacing bit levels 1-4 with the RS4 kernel while bit levels 5-8 will continue using the regular [u+v,v] kernel. Accordingly, the complexity of 4 of 8 bits is increased.

For any kernel with a larger alphabet size (i.e., GF(2^{m})) a kernel over GF(2^{m}) must always be mapped into m consecutive bits in the constellation (e.g., bit tuple [1,2] goes to the first outer code and bit tuple [3,4] goes to the second outer code) in order to benefit from the set partitioning labeling (maximal increase in the Euclidian distance between stages).

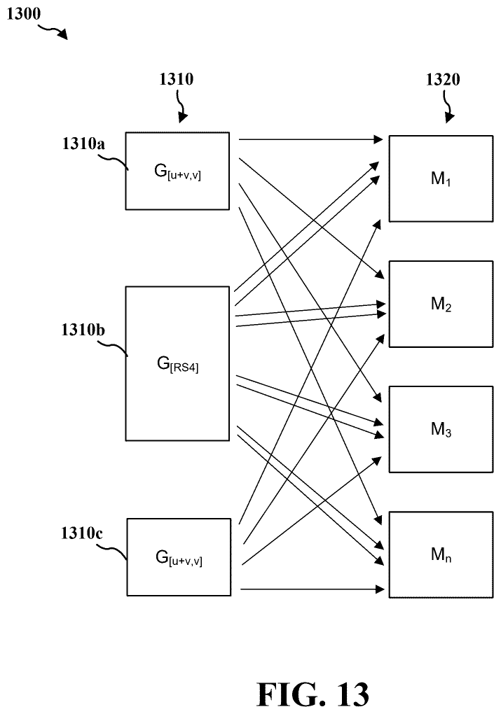

FIG. 13 is a diagram 1300 of an MLC scheme with outer codes 1310 having different polar code kernel types. In this MLC scheme, the number of outer codes 1310 (G_{N/m}) may be different than the number of bits in the constellation because at least one of the outer codes (e.g., outer code 1310b) may have an alphabet size greater than 2 (e.g., GF(4)) and output two bits. The outer code 1310b with the polar code kernel type that has an alphabet size greater than 2 is mapped to a number of consecutive bits equal to the GF over the alphabet size in the constellation for each modulation symbol 720. The outer codes G_{N/m,i} 1310 (e.g., 1310a and 1320c) with the second kernel type (e.g., the regular [u+v,v] kernel) are connected to a respective bit in the constellation for each modulation symbol 720.

In some implementations, the multi-level coding scheme maps a number of input bits to an order of the at least one first outer code and the at least one second outer code, wherein at least one second outer code is mapped to higher index bits than the at least one first outer code. For example, the second outer code 1310c may be mapped to a highest index bit. As another example, a first number of lowest index bits corresponding to an input size of the first polar code kernel type may be mapped to the at least one first outer code. For instance, the outer code 1310b may be the first outer code and be mapped to the first two indices of the input bits. In some implementations, information bits with a lowest capacity bit channel (e.g., bits in region 1120) are mapped to the at least one first outer code 1310b.

In an example implementation, the constellation size is 4 bits and the multi-level coding scheme applies a first bit to the second polar code kernel type (e.g., outer code 1310a), a second bit and a third bit to the first polar code kernel type (e.g., outer code 1310b), and a fourth bit to the second polar code kernel type (e.g., outer code 1310c). In another example, the constellation size is 4 bits and the multi-level coding scheme applies a first bit and a second bit to the first polar code kernel type, a third bit to the second polar code kernel type, and a fourth bit to the second polar code kernel type.

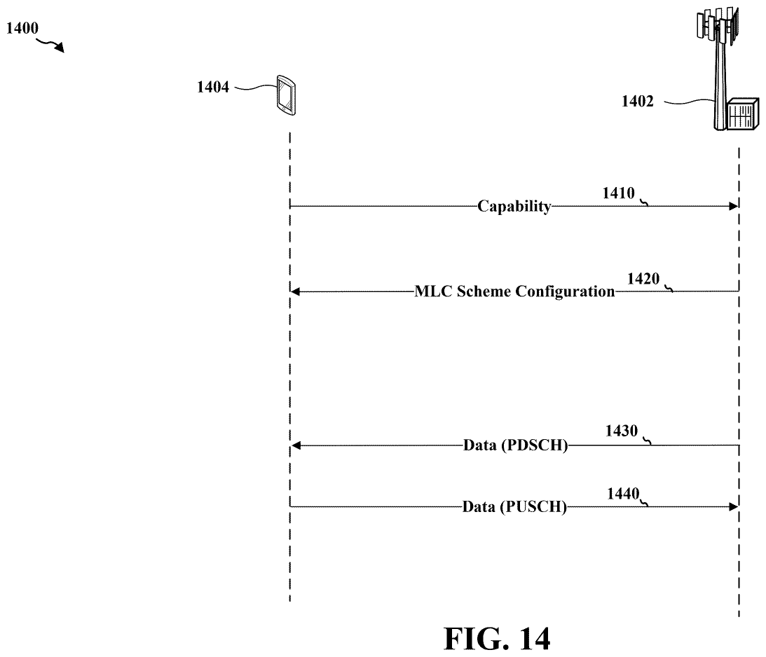

FIG. 14 is a message diagram illustrating configuration of a UE 1404 for MLC with different polar codes. The UE 1404 may communicate with a network entity 1402.

The UE 1404 may transmit a capability message 1410 that indicates a capability of the UE 1404 to support MLC with different polar codes. For example, the capability message 1410 may indicate a number of a first type of polar code kernel that the UE can handle. For instance, a UE may handle one or more RS4 kernels. In some implementations, the UE may indicate whether a location of the outer code using the first type of polar code kernel is flexible or whether there are any limits. For instance, the location of the first type of polar code kernel may be limited to one or more bit indices starting at a lowest bit index.

The network entity 1402 may transmit a MLC scheme configuration 1420. In some implementations, the MLC scheme configuration 1420 may be defined in relation to other transmission parameters. The MLC scheme configuration 1420 may indicate a predefined multi-level coding scheme that is associated with one or more of a user equipment category, a modulation and coding scheme (MCS), an index, or a capability. For instance, the MLC scheme configuration 1420 may indicate a MCS table to use that also includes the MLC scheme. In some implementations, the MLC scheme may be configurable via a DCI, MAC-CE, or RRC message. For instance, the network entity 1402 may transmit the MLC scheme configuration 1420 in response to the capability message 1410. For example, where the UE 1404 has indicated flexibility in the location of the first type of polar code kernel, the MLC scheme configuration 1420 may indicate a mapping of bit levels to kernels. As another example, a DCI may indicate an index of an MLC scheme to use for one or more transmissions.

The network entity 1402 may transmit a data transmission 1430 based on the MLC scheme. For example, the network entity 1402 may transmit a physical downlink shared channel (PDSCH) that is encoded using the MLC scheme. The PDSCH may use a modulation scheme having a constellation size more than 2 bits. The UE 1404 may decode the data transmission 1430 based on the MLC scheme. For instance, the UE 1404 may use an SCL decoder.

The UE 1404 may transmit a data transmission 1440 based on the MLC scheme. For example, the UE 1404 may transmit a physical uplink shared channel (PUSCH) that uses a modulation scheme with a constellation size more than 2 bits. In some implementations, the MLC scheme for uplink transmissions may be the same or different than the MLC scheme for downlink transmissions. For instance, the network entity 1402 may have greater capability for transmitting with kernels having greater polarization.

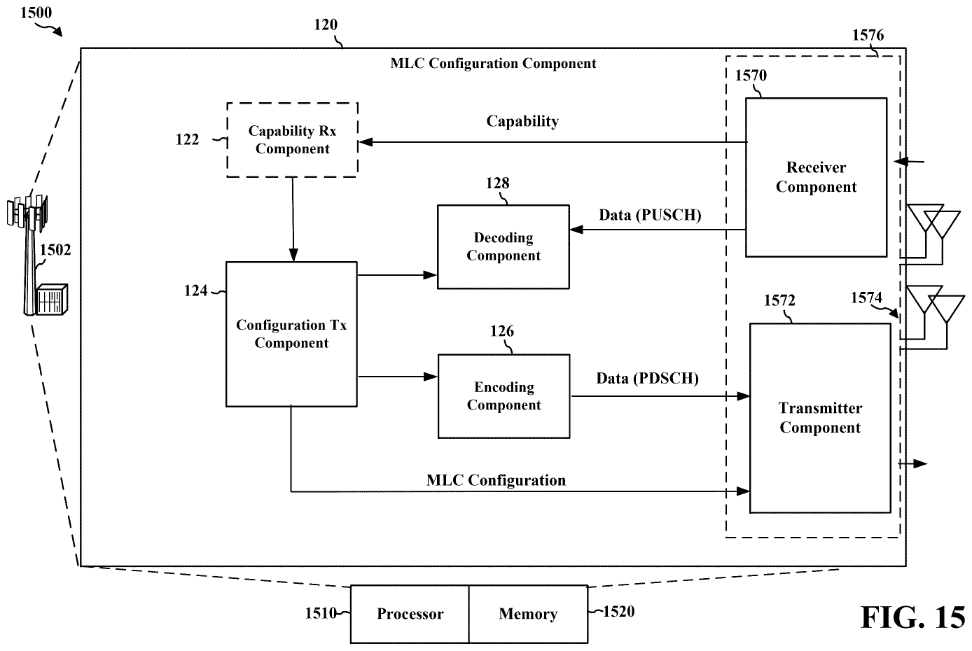

FIG. 15 is a conceptual data flow diagram 1500 illustrating the data flow between different means/components in an example network entity 1502 including a MLC configuration component 120. For example, the network entity 1502 may be an example of a network node such as the base station 102 (FIG. 1) including the MLC configuration component 120. In some implementations, the MLC configuration component 120 may be implemented by the memory 376 and the TX processor 316, the RX processor 370, and/or the controller/processor 375 of FIG. 3. For example, the memory 376 may store executable instructions defining the MLC configuration component 120 and the TX processor 316, the RX processor 370, and/or the controller/processor 375 may execute the instructions. In other implementations, the MLC configuration component 120 may be implemented on computing resources including one or more processors 1510 and one or more memories 1520. For example, the MLC configuration component 120 may be implemented on a virtual CU or virtual DU in a datacenter.

As discussed with respect to FIG. 1, the MLC configuration component 120 may include the capability Rx component 122, the configuration Tx component 124, the encoding component 126, and the decoding component 128.

The network entity 1502 may include a receiver component 1570, which may include, for example, a radio frequency (RF) receiver for receiving the signals described herein. The network entity 1502 may include a transmitter component 1572, which may include, for example, an RF transmitter for transmitting the signals described herein. The transmitter component 1572 may output RF signals to one or more antennas 1574. In an aspect, the receiver component 1570 and the transmitter component 1572 may be co-located in a transceiver 1576, which may correspond to the TX/RX 318 in FIG. 3.

The capability Rx component 122 is configured to receive a capability message indicating a capability of a user equipment with respect to the first polar code kernel type. For example, the capability Rx component 122 may receive the capability message 1410 via the receiver component 1570. For instance, the capability message 1410 may be an RRC message. In some implementations, the capability Rx component 122 may request the capability message 1410 by transmitting a capability request message. The capability Rx component 122 may output the capability of the UE to the configuration Tx component 124.

The configuration Tx component 124 is configured to transmit a configuration indicating a multi-level coding scheme for encoding a plurality of bits for transmission using a modulation scheme having a constellation size of more than 2 bits. In some implementations, the configuration Tx component 124 may select the multi-level coding scheme based on the capability of the UE. For instance, the configuration Tx component 124 may select a highest reliability multi-level coding scheme that the UE is capable of. In some implementations, the configuration Tx component 124 may select the multi-level coding scheme based on channel conditions. The configuration Tx component 124 may output the MLC scheme configuration 1420 for transmission via the transmitter component. In some implementations, the MLC scheme configuration 1420 indicates a indicates a predefined multi-level coding scheme that is associated with one or more of a user equipment category, a modulation and coding scheme, an index, or a capability. For instance, the MLC scheme configuration 1420 may be a DCI that indicates an index of a table. As another example, the MLC scheme configuration 1420 may be a MAC-CE that indicates a mapping of input bits to outer code kernel types. As yet another example, an RRC message may fully define a MLC scheme. The configuration Tx component 124 may also configure the encoding component 126 and the decoding component 128 with the MLC scheme.

The encoding component 126 is configured to encode bits for transmission using the multi-level coding scheme. For example, the encoding component 126 may be configured with the MLC scheme by the configuration Tx component 124. The encoding component 126 may receive unencoded information bits as a transmission block from higher layers (e.g., a RLC layer). The encoding component may add frozen bits defined by the MLC scheme. The encoding component 126 may encode the information bits and the frozen bits using the outer codes defined by the MLC scheme. The encoding component 126 may output encoded bits as symbols. A modulator may generate modulation symbols based on the encoded bits. The modulation symbols may be transmitted via the transmitter component 1572.

The decoding component 128 is configured to decode at least one modulated symbol based on the multi-level coding scheme. For instance, the decoding component 128 may be a successive cancellation list (SCL) decoder. The decoding component 128 may receive the at least one modulated symbol of a data transmission (e.g., PUSCH) via the receiver component 1570. The decoding component 128 may use the known frozen bits and the MCS scheme to decode each modulated symbol. The decoding component 128 may output information bits of the data transmission.

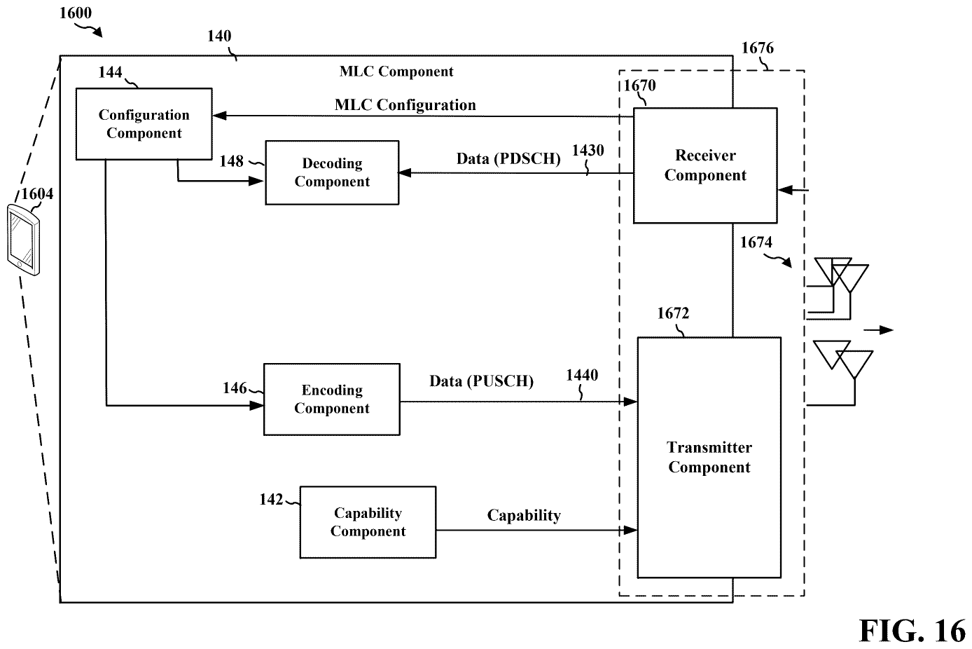

FIG. 16 is a conceptual data flow diagram 1600 illustrating the data flow between different means/components in an example UE 1604 including a MLC component 140. For example, the UE 1604 may be an example of a wireless node such as the UE 104 (FIG. 1) including the MLC component 140. The MLC component 140 may be implemented by the memory 360 and the TX processor 368, the RX processor 356, and/or the controller/processor 368 of FIG. 3. For example, the memory 360 may store executable instructions defining the MLC component 140 and the TX processor 368, the RX processor 356, and/or the controller/processor 359 may execute the instructions.

The UE 1604 may include a receiver component 1670, which may include, for example, a radio frequency (RF) receiver for receiving the signals described herein. The UE 1604 may include a transmitter component 1672, which may include, for example, an RF transmitter for transmitting the signals described herein. The transmitter component 1672 may output RF signals to one or more antennas 1674. In an aspect, the UE 1604 and the transmitter component 1672 may be co-located in a transceiver 1676, which may correspond to the TX/RX 354 in FIG. 3.

As discussed with respect to FIG. 1, the MLC component 140 may include the capability component 142, the configuration component 144, the encoding component 146, and the decoding component 148.

The receiver component 1670 may receive signals from a network entity such as a base station 102. For example, the receiver component 1670 may receive the MLC scheme configuration 1420 and the data transmission 1430. The receiver component 1670 may provide the MLC scheme configuration to the configuration component 144. The receiver component 1670 may provide the data transmission 1430 to the decoding component 148.

The capability component 142 is configured to transmit a capability message indicating a capability of a user equipment with respect to the first polar code kernel type. In some implementations, the capability message indicates a maximum number of codes of the first polar code kernel type. In some implementations, the capability message indicates whether a location of at least one first outer code with the first polar code kernel type within a number of input bits is flexible or whether there are any limitations on the location. The capability component 142 may output the capability message for transmission via the transmitter component 1672.

The configuration component 144 is configured to receive a configuration indicating a multi-level coding scheme for encoding a plurality of bits for transmission using a modulation scheme having a constellation size more than 2 bits. The multi-level coding scheme has at least one first outer code with a first polar code kernel type and at least one second outer code with a second polar code kernel type that is different than the first polar code kernel type. The configuration component 144 may receive the MLC scheme configuration 1420 via the receiver component 1670. The configuration component 144 may configure the encoding component 146 and the decoding component 148 with the MLC scheme.

The encoding component 146 is configured to encode bits for transmission using the multi-level coding scheme. For example, the encoding component 146 may be configured with the MLC scheme by the configuration component 144. The encoding component 146 may receive unencoded information bits as a transmission block from higher layers (e.g., a RLC layer). The encoding component 146 may add frozen bits defined by the MLC scheme. The encoding component 146 may encode the information bits and the frozen bits using the outer codes defined by the MLC scheme. The encoding component 146 may output encoded bits as symbols. A modulator may generate modulation symbols based on the encoded bits. The modulation symbols may be transmitted via the transmitter component 1672.

The decoding component 148 is configured to decode at least one modulated symbol based on the multi-level coding scheme. For instance, the decoding component 148 may be a successive cancellation list (SCL) decoder. The decoding component 148 may receive the at least one modulated symbol of a data transmission (e.g., PDSCH) via the receiver component 1670. The decoding component 148 may use the known frozen bits and the MCS scheme to decode each modulated symbol. The decoding component 148 may output information bits of the data transmission to higher layers.

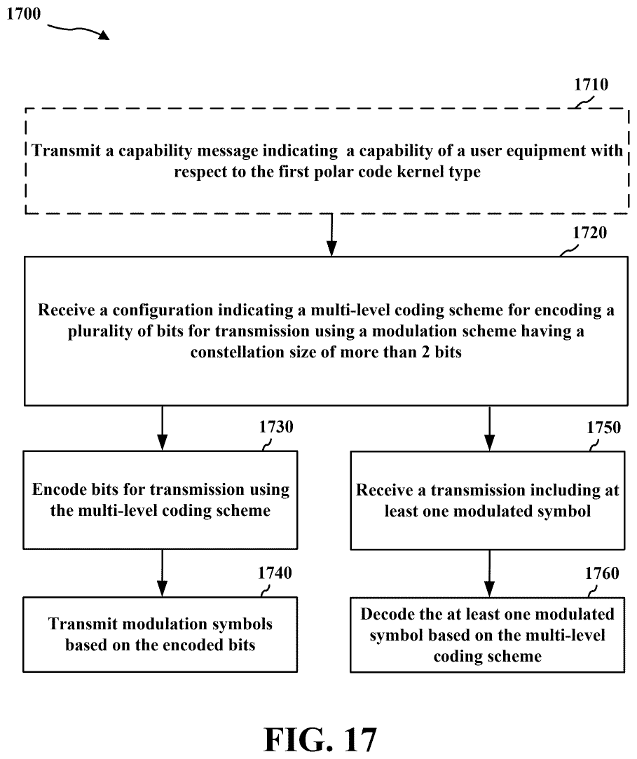

FIG. 17 is a flowchart of an example method 1700 for a wireless node such as a UE to utilize a MLC scheme with different polar code kernels. The method 1700 may be performed by a UE (such as the UE 104, which may include the memory 360 and which may be the entire UE 104 or a component of the UE 104 such as the MLC component 140, TX processor 368, the RX processor 356, or the controller/processor 359). The method 1700 may be performed by the MLC component 140 in communication with the MLC configuration component 120 at a network entity. Optional blocks are shown with dashed lines.

At block 1710, the method 1700 may optionally include transmitting a capability message indicating a capability of a user equipment with respect to the first polar code kernel type. In some implementations, for example, the UE 104, the Tx processor 368 or the controller/processor 359 may execute the MLC component 140 or the capability component 142 to transmit a capability message 1410 indicating a capability of a user equipment with respect to the first polar code kernel type. In some implementations, the capability message indicates a maximum number of codes of the first polar code kernel type. In some implementations, the capability message indicates whether a location of the at least one first outer code within a number of input bits is flexible or whether there are any limitations on the location. Accordingly, the UE 104, the TX processor 368, or the controller/processor 359 executing the MLC component 140 or the capability component 142 may provide means for transmitting a capability message indicating a capability of a user equipment with respect to the first polar code kernel type.

At block 1720, the method 1700 includes receiving a configuration indicating a multi-level coding scheme for encoding a plurality of bits for transmission using a modulation scheme having a constellation size of more than 2 bits. In some implementations, for example, the UE 104, the RX processor 356 or the controller/processor 359 may execute the MLC component 140 or the configuration component 144 to receive a configuration (e.g., MLC scheme configuration 1420) indicating a multi-level coding scheme for encoding a plurality of bits for transmission using a modulation scheme having a constellation size of more than 2 bits.

The multi-level coding scheme has at least one first outer code 1310b with a first polar code kernel type and at least one second outer code 1310a with a second polar code kernel type that is different than the first polar code kernel type. In some implementations, the first polar code kernel type is a better polarizing kernel than the second polar code kernel type. For instance, the first polar code kernel type may be a RS4 kernel over a quadratic alphabet. The second polar code kernel type may be a [u+v, v] kernel over a binary alphabet. In some implementations, the first polar code kernel type has an alphabet size greater than 2 and the first outer code is mapped to a number of consecutive bits equal to a Galois field (GF) over the alphabet size.

In some implementations, configuration indicates a predefined multi-level coding scheme that is associated with one or more of a user equipment category, a modulation and coding scheme, an index, or a capability. In some implementations, the configuration indicates a mapping of input bit levels to the at least one first outer code and the at least one second outer code. In some implementations, the multi-level coding scheme maps a number of input bits to an order of the at least one first outer code and the at least one second outer code, wherein at least one second outer code is mapped to higher index bits than the at least one first outer code. For example, a first number of lowest index bits corresponding to an input size of the first polar code kernel type may be mapped to the at least one first outer code. As another example, information bits with a lowest capacity bit channel may be mapped to the at least one first outer code.

In view of the foregoing, the UE 104, the RX processor 356, or the controller/processor 359 executing the MLC component 140 or the configuration component 144 may provide means for receiving a configuration indicating a multi-level coding scheme for encoding a plurality of bits for transmission using a modulation scheme having a constellation size of more than 2 bits.

At block 1730, the method 1700 includes encoding bits for transmission using the multi-level coding scheme. In some implementations, for example, the UE 104, the TX processor 368 or the controller/processor 359 may execute the MLC component 140 or the encoding component 146 to encode bits for transmission using the multi-level coding scheme. Accordingly, the UE 104, the TX processor 368, or the controller/processor 359 executing the MLC component 140 or the encoding component 146 may provide means for encoding bits for transmission using the multi-level coding scheme.

At block 1740, the method 1700 includes transmitting modulation symbols based on the encoded bits. In some implementations, for example, the UE 104, the RX processor 356 or the controller/processor 359 may execute the MLC component 140 or the transmitter component 1672 to transmit modulation symbols based on the encoded bits. Accordingly, the UE 104, the TX processor 368, or the controller/processor 359 executing the MLC component 140 or the transmitter component 1672 may provide means for transmitting modulation symbols based on the encoded bits.

At block 1750, the method 1700 includes receiving a transmission including at least one modulated symbol. In some implementations, for example, the UE 104, the RX processor 356 or the controller/processor 359 may execute the MLC component 140 or the receiver component 1670 to receive a transmission including at least one modulated symbol. Accordingly, the UE 104, the RX processor 356, or the controller/processor 359 executing the MLC component 140 or the receiver component 1670 may provide means for receiving a transmission including at least one modulated symbol.

At block 1760, the method 1700 includes decoding the at least one modulated symbol based on the multi-level coding scheme. In some implementations, for example, the UE 104, the RX processor 356 or the controller/processor 359 may execute the MLC component 140 or the decoding component 148 to decode the at least one modulated symbol based on the multi-level coding scheme. Accordingly, the UE 104, the RX processor 356, or the controller/processor 359 executing the MLC component 140 or the decoding component 148 may provide means for decoding the at least one modulated symbol based on the multi-level coding scheme.

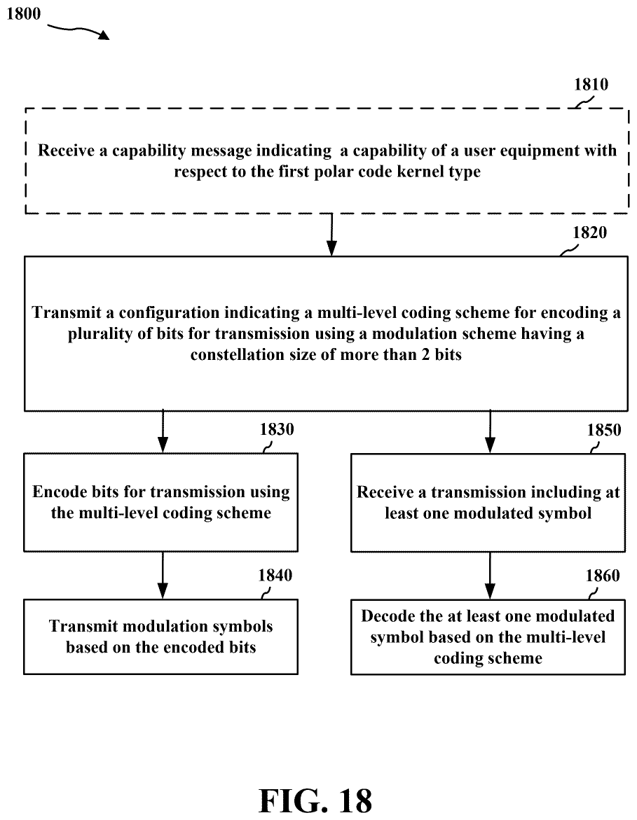

FIG. 18 is a flowchart of an example method 1800 for a wireless node such as a network entity to communicate with a UE using an MLC scheme with different polar code kernels. The method 1800 may be performed by a network entity 1502 such as a base station (such as the base station 102, which may include the memory 376 and which may be the entire base station 102 or a component of the base station 102 such as a DU 430 including the MLC configuration component 120, TX processor 316, RX processor 370, or the controller/processor 375). The method 1800 may be performed by the MLC configuration component 120 in communication with the MLC component 140 at a UE. Optional blocks are shown with dashed lines.

At block 1810, the method 1800 may optionally include receiving a capability message indicating a capability of a user equipment with respect to the first polar code kernel type. In some implementations, for example, the base station 102, the RX processor 370 or the controller/processor 375 may execute the MLC configuration component 120 or the capability component 122 to receive the capability message 1410 indicating the capability of the UE 104 with respect to the first polar code kernel type. In some implementations, the capability message indicates a maximum number of codes of the first polar code kernel type. In some implementations, the capability message indicates whether a location of the at least one first outer code within a number of input bits is flexible or whether there are any limitations on the location. Accordingly, the base station 102, the RX processor 370 or the controller/processor 375 executing the MLC configuration component 120 or the capability component 122 may provide means for receiving a capability message indicating a capability of a user equipment with respect to the first polar code kernel type.

At block 1820, the method 1800 includes transmitting a configuration indicating a multi-level coding scheme for encoding a plurality of bits for transmission using a modulation scheme having a constellation size of more than 2 bits. In some implementations, for example, the base station 102, the TX processor 316, or the controller/processor 375 may execute the MLC configuration component 120 or the configuration Tx component 124 to transmit a configuration (e.g., MLC scheme configuration 1420) indicating a multi-level coding scheme for encoding a plurality of bits for transmission using a modulation scheme having a constellation size of more than 2 bits.

In view of the foregoing, the UE 104, the base station 102, the TX processor 316, or the controller/processor 375 executing the MLC configuration component 120 or the configuration Tx component 124 may provide means for transmitting a configuration indicating a multi-level coding scheme for encoding a plurality of bits for transmission using a modulation scheme having a constellation size of more than 2 bits.

At block 1830, the method 1800 includes encoding bits for transmission using the multi-level coding scheme. In some implementations, for example, the base station 102, the TX processor 316, or the controller/processor 375 may execute the MLC configuration component 120 or the encoding component 126 to encode bits for transmission using the multi-level coding scheme. Accordingly, base station 102, the TX processor 316, or the controller/processor 375 executing the MLC configuration component 120 or the encoding component 126 may provide means for encoding bits for transmission using the multi-level coding scheme.

At block 1840, the method 1800 includes transmitting modulation symbols based on the encoded bits. In some implementations, for example, the base station 102, the TX processor 316 or the controller/processor 375 may execute the MLC configuration component 120 or the transmitter component 1572 to transmit modulation symbols based on the encoded bits. Accordingly, the base station 102, the TX processor 316, or the controller/processor 375 executing the MLC configuration component 120 or the transmitter component 1572 may provide means for transmitting modulation symbols based on the encoded bits.

At block 1850, the method 1800 includes receiving a transmission including at least one modulated symbol. In some implementations, for example, the base station 102, the RX processor 370 or the controller/processor 375 may execute the MLC configuration component 120 or the receiver component 1570 to receive a transmission including at least one modulated symbol. Accordingly, the base station 102, the RX processor 370, or the controller/processor 375 executing the MLC configuration component 120 or the receiver component 1570 may provide means for receiving a transmission including at least one modulated symbol.

At block 1860, the method 1800 includes decoding the at least one modulated symbol based on the multi-level coding scheme. In some implementations, for example, the base station 102, the RX processor 370 or the controller/processor 375 may execute the MLC configuration component 120 or the decoding component 128 to decode the at least one modulated symbol based on the multi-level coding scheme. Accordingly, the base station 102, the RX processor 370, or the controller/processor 375 executing the MLC configuration component 120 or the decoding component 128 may provide means for decoding the at least one modulated symbol based on the multi-level coding scheme.

The following numbered clauses provide an overview of aspects of the present disclosure:

Clause 1. An apparatus for wireless communication, the apparatus comprising: one or more memories storing executable instructions; and one or more processors coupled to the one or more memories and configured to execute the instructions to cause the apparatus to: receive a configuration indicating a multi-level coding scheme for encoding a plurality of bits for transmission using a modulation scheme having a constellation size of more than 2 bits, wherein the multi-level coding scheme has at least one first outer code with a first polar code kernel type and at least one second outer code with a second polar code kernel type that is different than the first polar code kernel type.

Clause 2. The apparatus of clause 1, wherein the one or more processors, individually or in combination are configured to execute the instructions to cause the apparatus to: encode bits for transmission using the multi-level coding scheme; and transmit modulation symbols based on the encoded bits.

Clause 3. The apparatus of clause 1 or 2, wherein the one or more processors, individually or in combination are configured to execute the instructions to cause the apparatus to: receive a transmission including at least one modulated symbol; and decode the at least one modulated symbol based on the multi-level coding scheme.

Clause 4. The apparatus of any of clauses 1-3, wherein the first polar code kernel type is a better polarizing kernel than the second polar code kernel type.

Clause 5. The apparatus of any of clauses 14, wherein the one or more processors, individually or in combination are configured to execute the instructions to cause the apparatus to transmit a capability message indicating a capability of a user equipment with respect to the first polar code kernel type.

Clause 6. The apparatus of clause 5, wherein the capability message indicates a maximum number of codes of the first polar code kernel type.

Clause 7. The apparatus of clause 5, wherein the capability message indicates whether a location of the at least one first outer code within a number of input bits is flexible or whether there are any limitations on the location.

Clause 8. The apparatus of clause 5, wherein the configuration indicates a mapping of input bit levels to the at least one first outer code and the at least one second outer code.

Clause 9. The apparatus of any of clauses 1-8, wherein the configuration indicates a predefined multi-level coding scheme that is associated with one or more of a user equipment category, a modulation and coding scheme, an index, or a capability.

Clause 10. The apparatus of any of clauses 1-8, wherein the multi-level coding scheme maps a number of input bits to an order of the at least one first outer code and the at least one second outer code, wherein at least one second outer code is mapped to higher index bits than the at least one first outer code.

Clause 11. The apparatus of clause 10, wherein a first number of lowest index bits corresponding to an input size of the first polar code kernel type are mapped to the at least one first outer code.

Clause 12. The apparatus of clause 10, wherein information bits with a lowest capacity bit channel are mapped to the at least one first outer code.

Clause 13. The apparatus of any of clauses 1-12, wherein the first polar code kernel type has an alphabet size greater than 2 and the first outer code is mapped to a number of consecutive bits equal to a Galois field (GF) over the alphabet size.

Clause 14. The apparatus of any of clauses 1-13, wherein the first polar code kernel type is a Reed-Solomon 4 (RS4) kernel over a quadratic alphabet.

Clause 15. The apparatus of clause 14, wherein the second polar code kernel type is a [u+v, v] kernel over a binary alphabet.

Clause 16. The apparatus of any of clauses 1-15, wherein the transmission is a physical shared data channel.

Clause 17. An apparatus for wireless communication, the apparatus comprising: one or more memories storing executable instructions; and one or more processors coupled to the one or more memories and configured to execute the instructions to cause the apparatus to: transmit a configuration indicating a multi-level coding scheme for encoding a plurality of bits for transmission using a modulation scheme having a constellation size of more than 2 bits, wherein the multi-level coding scheme has at least one first outer code with a first polar code kernel type and at least one second outer code with a second polar code kernel type that is different than the first polar code kernel type.

Clause 18. The apparatus of clause 17, wherein the one or more processors, individually or in combination are configured to execute the instructions to cause the apparatus to: encode bits for transmission using the multi-level coding scheme; and transmit modulation symbols based on the encoded bits.

Clause 19. The apparatus of clause 17 or 18, wherein the one or more processors, individually or in combination are configured to execute the instructions to cause the apparatus to: receive a transmission including at least one modulated symbol; and decode the at least one modulated symbol based on the multi-level coding scheme.

Clause 20. The apparatus of any of clauses 17-19, wherein the first polar code kernel type is a better polarizing kernel than the second polar code kernel type.

Clause 21. The apparatus of any of clauses 17-20, wherein the one or more processors, individually or in combination are configured to execute the instructions to cause the apparatus to receive a capability message indicating a capability of a user equipment with respect to the first polar code kernel type.

Clause 22. The apparatus of any of clauses 17-20, wherein the configuration indicates a predefined multi-level coding scheme that is associated with one or more of a user equipment category, a modulation and coding scheme, an index, or a capability.

Clause 23. A method of wireless communication, comprising: receiving a configuration indicating a multi-level coding scheme for encoding a plurality of bits for transmission using a modulation scheme having a constellation size of more than 2 bits, wherein the multi-level coding scheme has at least one first outer code with a first polar code kernel type and at least one second outer code with a second polar code kernel type that is different than the first polar code kernel type.

Clause 24. The method of clause 23, further comprising: encoding bits for transmission using the multi-level coding scheme; and transmitting modulation symbols based on the encoded bits.

Clause 25. The method of clause 23 or 24, further comprising: receiving a transmission including at least one modulated symbol; and decoding the at least one modulated symbol based on the multi-level coding scheme.

Clause 26. The method of any of clauses 23-25, wherein the first polar code kernel type is a better polarizing kernel than the second polar code kernel type.

Clause 27. The method of any of clauses 23-26, further comprising transmitting a capability message indicating a capability of a user equipment with respect to the first polar code kernel type.

Clause 28. The method of any of clauses 23-26, wherein the configuration indicates a predefined multi-level coding scheme that is associated with one or more of a user equipment category, a modulation and coding scheme, an index, or a capability.

Clause 29. The method of any of clauses 23-28, wherein the first polar code kernel type has an alphabet size greater than 2 and the first outer code is mapped to a number of consecutive bits equal to a Galois field (GF) over the alphabet size.

Clause 30. A method of wireless communication, comprising: transmitting a configuration indicating a multi-level coding scheme for encoding a plurality of bits for transmission using a modulation scheme having a constellation size of more than 2 bits, wherein the multi-level coding scheme has at least one first outer code with a first polar code kernel type and at least one second outer code with a second polar code kernel type that is different than the first polar code kernel type.

As used herein, a phrase referring to “at least one of” a list of items refers to any combination of those items, including single members. As an example, “at least one of: a, b, or c” is intended to cover: a, b, c, a-b, a-c, b-c, and a-b-c. Similarly, as used herein, a phrase referring to “one or more of” a list of items refers to any combination of those items, including single members. As an example, “one or more of: a, b, or c” is intended to cover: a, b, c, a-b, a-c, b-c, and a-b-c.

The various illustrative logics, logical blocks, modules, circuits and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular processes and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

If implemented in software, the functions may be stored on or transmitted over as one or more instructions or code on a computer-readable medium. The processes of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and Blu-ray disc where disks usually reproduce data magnetically, while discs reproduce data optically with lasers. Combinations of the above should also be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of any device as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An apparatus for wireless communication, the apparatus comprising:
one or more memories storing executable instructions; and
one or more processors coupled to the one or more memories and configured to execute the instructions to cause the apparatus to:
receive a configuration indicating a multi-level coding scheme for encoding a plurality of bits for transmission using a modulation scheme having a constellation size of more than 2 bits,
wherein the multi-level coding scheme has at least one first outer code with a first polar code kernel type and at least one second outer code with a second polar code kernel type that is different than the first polar code kernel type.

2. The apparatus of claim 1, wherein the one or more processors, individually or in combination are configured to execute the instructions to cause the apparatus to:
encode bits for transmission using the multi-level coding scheme; and
transmit modulation symbols based on the encoded bits.

3. The apparatus of claim 1, wherein the one or more processors, individually or in combination are configured to execute the instructions to cause the apparatus to:
receive a transmission including at least one modulated symbol; and
decode the at least one modulated symbol based on the multi-level coding scheme.

4. The apparatus of claim 1, wherein the first polar code kernel type is a better polarizing kernel than the second polar code kernel type.

5. The apparatus of claim 1, wherein the one or more processors, individually or in combination are configured to execute the instructions to cause the apparatus to transmit a capability message indicating a capability of a user equipment with respect to the first polar code kernel type.

6. The apparatus of claim 5, wherein the capability message indicates a maximum number of codes of the first polar code kernel type.

7. The apparatus of claim 5, wherein the capability message indicates whether a location of the at least one first outer code within a number of input bits is flexible or whether there are any limitations on the location.

8. The apparatus of claim 5, wherein the configuration indicates a mapping of input bit levels to the at least one first outer code and the at least one second outer code.

9. The apparatus of claim 1, wherein the configuration indicates a predefined multi-level coding scheme that is associated with one or more of a user equipment category, a modulation and coding scheme, an index, or a capability.

10. The apparatus of claim 1, wherein the multi-level coding scheme maps a number of input bits to an order of the at least one first outer code and the at least one second outer code, wherein at least one second outer code is mapped to higher index bits than the at least one first outer code.

11. The apparatus of claim 10, wherein a first number of lowest index bits corresponding to an input size of the first polar code kernel type are mapped to the at least one first outer code.

12. The apparatus of claim 10, wherein information bits with a lowest capacity bit channel are mapped to the at least one first outer code.

13. The apparatus of claim 1, wherein the first polar code kernel type has an alphabet size greater than 2 and the first outer code is mapped to a number of consecutive bits equal to a Galois field (GF) over the alphabet size.

14. The apparatus of claim 1, wherein the first polar code kernel type is a Reed-Solomon 4 (RS4) kernel over a quadratic alphabet.

15. The apparatus of claim 14, wherein the second polar code kernel type is a [u+v, v] kernel over a binary alphabet.

16. The apparatus of claim 1, wherein the transmission is a physical shared data channel.

17. An apparatus for wireless communication, the apparatus comprising:
one or more memories storing executable instructions; and
one or more processors coupled to the one or more memories and configured to execute the instructions to cause the apparatus to:
transmit a configuration indicating a multi-level coding scheme for encoding a plurality of bits for transmission using a modulation scheme having a constellation size of more than 2 bits,
wherein the multi-level coding scheme has at least one first outer code with a first polar code kernel type and at least one second outer code with a second polar code kernel type that is different than the first polar code kernel type.

18. The apparatus of claim 17, wherein the one or more processors, individually or in combination are configured to execute the instructions to cause the apparatus to:
encode bits for transmission using the multi-level coding scheme; and
transmit modulation symbols based on the encoded bits.

19. The apparatus of claim 17, wherein the one or more processors, individually or in combination are configured to execute the instructions to cause the apparatus to:
receive a transmission including at least one modulated symbol; and
decode the at least one modulated symbol based on the multi-level coding scheme.

20. The apparatus of claim 17, wherein the first polar code kernel type is a better polarizing kernel than the second polar code kernel type.

21. The apparatus of claim 17, wherein the one or more processors, individually or in combination are configured to execute the instructions to cause the apparatus to receive a capability message indicating a capability of a user equipment with respect to the first polar code kernel type.

22. The apparatus of claim 17, wherein the configuration indicates a predefined multi-level coding scheme that is associated with one or more of a user equipment category, a modulation and coding scheme, an index, or a capability.

23. A method of wireless communication, comprising:
receiving a configuration indicating a multi-level coding scheme for encoding a plurality of bits for transmission using a modulation scheme having a constellation size of more than 2 bits,
wherein the multi-level coding scheme has at least one first outer code with a first polar code kernel type and at least one second outer code with a second polar code kernel type that is different than the first polar code kernel type.

24. The method of claim 23, further comprising:
encoding bits for transmission using the multi-level coding scheme; and
transmitting modulation symbols based on the encoded bits.

25. The method of claim 23, further comprising:
receiving a transmission including at least one modulated symbol; and
decoding the at least one modulated symbol based on the multi-level coding scheme.

26. The method of claim 23, wherein the first polar code kernel type is a better polarizing kernel than the second polar code kernel type.

27. The method of claim 23, further comprising transmitting a capability message indicating a capability of a user equipment with respect to the first polar code kernel type.

28. The method of claim 23, wherein the configuration indicates a predefined multi-level coding scheme that is associated with one or more of a user equipment category, a modulation and coding scheme, an index, or a capability.

29. The method of claim 23, wherein the first polar code kernel type has an alphabet size greater than 2 and the first outer code is mapped to a number of consecutive bits equal to a Galois field (GF) over the alphabet size.

30. A method of wireless communication, comprising:
transmitting a configuration indicating a multi-level coding scheme for encoding a plurality of bits for transmission using a modulation scheme having a constellation size of more than 2 bits,
wherein the multi-level coding scheme has at least one first outer code with a first polar code kernel type and at least one second outer code with a second polar code kernel type that is different than the first polar code kernel type.
